(19) United States
(12) Patent Application Publication
(10) Pub. No.: US 2024/0419008 A1
(43) Pub. Date: Dec. 19, 2024

(54) ELECTRONIC DEVICE

(71) Applicant: SEMICONDUCTOR ENERGY LABORATORY CO., LTD., Atsugi-shi, Kanagawa-ken (JP)

(72) Inventors: Ryo HATSUMI, Hadano, Kanagawa (JP); Hisao IKEDA, Zama, Kanagawa (JP); Daiki NAKAMURA, Atsugi, Kanagawa (JP); Takeya HIROSE, Atsugi, Kanagawa (JP); Yosuke TSUKAMOTO, Atsugi, Kanagawa (JP)

(21) Appl. No.: 18/722,062

(22) PCT Filed: Dec. 9, 2022
(86) PCT No.: PCT/IB2022/061952

§ 371 Date: Jun. 20, 2024

(30) Foreign Application Priority Data
Dec. 24, 2021 (JP) 2021-210207

(51) Int. Cl. G02B 27/09; G02B 25/00; H10K 59/80

(52) U.S. Cl. CPC G02B 27/0905; G02B 25/001; G02B 27/0977; H10K 59/879

(57) ABSTRACT

An electronic device that can provide a high sense of immersion is provided. An electronic device with low power consumption is provided. The electronic device includes a first display device, a second display device, a first half mirror, an eyepiece lens, and a first lens. The first display device displays a first image, and the second display device displays a second image. The first display device is provided at a position so that the first image is reflected by the first half mirror and enters the eyepiece lens. The second display device is provided at a position so that the second image passes through the first half mirror and enters the eyepiece lens. The first lens is provided between the second display device and the first half mirror. The pixel density of the first display device and that of the second display device are equal to each other. The first image is presented with a first viewing angle through the eyepiece lens, and the second image is presented with a second viewing angle greater than the first viewing angle through the eyepiece lens.

### TECHNICAL FIELD

One embodiment of the present invention relates to a display device. One embodiment of the present invention relates to an electronic device including a display device.

Note that one embodiment of the present invention is not limited to the above technical field. Examples of the technical field of one embodiment of the present invention disclosed in this specification and the like include a semiconductor device, a display device, a light-emitting apparatus, a power storage device, a storage device, an electronic device, a lighting device, an input device, an input/output device, a driving method thereof, and a fabrication method thereof. A semiconductor device refers to any device that can function by utilizing semiconductor characteristics.

### BACKGROUND ART

As electronic devices provided with display devices for augmented reality (AR) or virtual reality (VR), wearable electronic devices are becoming widespread. Examples of wearable electronic devices include a head-mounted display (HMD) and an eyeglass-type electronic device.

When using an electronic device such as an HMD with a short distance between a display portion and a user, the user is likely to perceive pixels and strongly feels granularity, whereby the sense of immersion and realistic sensation of AR or VR might be diminished. Thus, an HMD is preferably provided with a display device that has minute pixels so that the pixels are not perceived by the user. Patent Document 1 discloses a method in which an HMD including minute pixels is achieved by using minute transistors capable of high-speed operation.

### REFERENCE

### Patent Document

[Patent Document 1] Japanese Published Patent Application No. 2000-2856

### SUMMARY OF THE INVENTION

### Problems to be Solved by the Invention

An object of one embodiment of the present invention is to provide an electronic device providing a high sense of immersion. Another object is to provide an electronic device with high display quality. Another object is to provide an electronic device capable of displaying an image with a higher resolution as the image is closer to a gaze point. Another object is to provide an electronic device with low-power consumption. Another object is to provide an electronic device capable of being manufactured at low cost. Another object is to provide an electronic device having a novel structure.

Another object of one embodiment of the present invention is to provide a display device with a novel structure or an electronic device with a novel structure. Another object of one embodiment of the present invention is to at least alleviate at least one of problems of the conventional technique.

Note that the description of these objects does not preclude the existence of other objects. Note that one embodiment of the present invention does not need to achieve all of these objects. Note that objects other than these can be derived from the description of the specification, the drawings, the claims, and the like.

### Means for Solving the Problems

One embodiment of the present invention is a display device including a first display device, a second display device, an eyepiece lens, and a first lens. The first display device has a function of displaying a first image. The second display device has a function of displaying a second image. A pixel density of the first display device is equal to a pixel density of the second display device. The first image is presented through the eyepiece lens. The second image is magnified by the first lens and presented through the eyepiece lens.

Another embodiment of the present invention includes a first display device, a second display device, a first half mirror, an eyepiece lens, and a first lens. The first display device has a function of displaying a first image. The second display device has a function of displaying a second image. The first display device is provided at a position so that the first image is reflected by the first half mirror and enters the eyepiece lens. The second display device is provided at a position so that the second image passes through the first half mirror and enters the eyepiece lens. The first lens is provided between the second display device and the first half mirror. A pixel density of the first display device is equal to a pixel density of second display device. The first image is presented with a first viewing angle through the eyepiece lens. The second image is presented with a second viewing angle greater than the first viewing angle through the eyepiece lens.

Another embodiment of the present invention includes a first display device, a second display device, a first half mirror, an eyepiece lens, and a first lens. The first display device has a function of displaying a first image. The second display device has a function of displaying a second image. The first display device is provided at a position so that the first image passes through the first half mirror and enters the eyepiece lens. The second display device is provided at a position so that the second image is reflected by the first half mirror and enters the eyepiece lens. The first lens is provided between the second display device and the first half mirror. A pixel density of the first display device is equal to a pixel density of the second display device. The first image is presented with a first viewing angle through the eyepiece lens. The second image is presented with a second viewing angle greater than the first viewing angle through the eyepiece lens.

In any of the above, a second lens is preferably provided between the first display device and the first half mirror.

In any of the above, the first viewing angle is preferably greater than or equal to 5° and less than or equal to 30°. The second viewing angle is preferably greater than that of the first viewing angle and less than or equal to 220°.

In any of the above, an outline of the first image is preferably a circle or an ellipse.

In any of the above, a center portion of the first image is preferably shown at a first resolution, and a surrounding portion outside the center portion is preferably shown at a second resolution lower than the first resolution. Furthermore, the second resolution is preferably higher than or equal to a resolution of the second image when the second image is seen through the eyepiece lens.

In any of the above, each of the first display device and the second display device preferably has a pixel density higher than or equal to 1000 ppi and lower than or equal to 20000 ppi.

In any of the above, a third display device, a third lens, and a second half mirror are further preferably included. In this case, the third display device has a function of displaying a third image. Furthermore, the third display device is provided at a position so that the third image is reflected by the second half mirror and enters the eyepiece lens. The third lens is provided between the third display device and the second half mirror.

In any of the above, each of the first display device and the second display device preferably includes a plurality of light-emitting elements and a plurality of color filters. In this case, each of the light-emitting elements preferably includes an organic layer emitting white light. In this case, furthermore, the organic layer is preferably divided between two of the light-elements adjacent to each other.

In any of the above, each of the first display device and the second display device preferably includes a first light-emitting element and a second light-emitting element. Furthermore, the first light-emitting element and the second light-emitting element preferably include different light-emitting materials.

### Effect of the Invention

According to one embodiment of the present invention, an electronic device capable of providing a high sense of immersion can be provided. Alternatively, an electronic device with high display quality can be provided. Alternatively, an electronic device capable of displaying an image with a higher resolution as the image is closer to a gaze point can be provided. Alternatively, an electronic device with low power consumption can be provided. Alternatively, an electronic device capable of being manufactured at low cost can be provided. Alternatively, an electronic device having a novel structure can be provided.

According to another embodiment of the present invention, a display device with a novel structure or an electronic device with a novel structure can be provided. According to another embodiment of the present invention, at least one of problems of the conventional technique can be at least alleviated.

Note that the description of these effects does not preclude the existence of other effects. One embodiment of the present invention does not necessarily need to have all of these effects. Note that effects other than these can be derived from the description of the specification, the drawings, the claims, and the like.

### BRIEF DESCRIPTION OF THE DRAWINGS

FIG. 1A to FIG. 1C are diagrams illustrating structure examples of an electronic device.

FIG. 2A to FIG. 2C are diagrams illustrating structure examples of an electronic device.

FIG. 3A to FIG. 3C are diagrams illustrating structure examples of an electronic device.

FIG. 4A to FIG. 4C are diagrams illustrating structure examples of an electronic device.

FIG. 5 is a diagram illustrating a structure example of an electronic device.

FIG. 6A to FIG. 6C are diagrams illustrating structure examples of an electronic device.

FIG. 7A and FIG. 7B are diagrams illustrating a structure example of an electronic device.

FIG. 8A to FIG. 8C are diagrams illustrating a structure example of a display device.

FIG. 9A and FIG. 9B are diagrams each illustrating a structure example of a display device.

FIG. 10A to FIG. 10F are diagrams each illustrating a structure example of a pixel.

FIG. 11A and FIG. 11B are diagrams illustrating a structure example of a display device.

FIG. 12 is a diagram illustrating a structure example of a display device.

FIG. 13 is a diagram illustrating a structure example of a display device.

FIG. 14 is a diagram illustrating a structure example of a display device.

FIG. 15 is a diagram illustrating a structure example of a display device.

FIG. 16 is a diagram illustrating a structure example of a display device.

FIG. 17 is a diagram illustrating a structure example of a display device.

FIG. 18 is a diagram illustrating a structure example of a display device.

FIG. 19A to FIG. 19F are diagrams each illustrating a structure example of a light-emitting device.

FIG. 20A to FIG. 20C are diagrams each illustrating a structure example of a light-emitting device.

### MODE FOR CARRYING OUT THE INVENTION

Embodiments are described below with reference to the drawings. Note that the embodiments can be implemented with many different modes, and it will be readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and description thereof is not repeated. The same hatching pattern is applied to portions having similar functions, and the portions are not especially denoted by reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, the ordinal numbers such as “first” and “second” are used in order to avoid confusion among components and do not limit the number of components.

In this specification and the like, a display panel that is one embodiment of a display device has a function of displaying (outputting) an image or the like on (to) a display surface. Therefore, the display panel is one embodiment of an output device.

In this specification and the like, a structure in which a connector such as an FPC (Flexible Printed Circuit) or a TCP (Tape Carrier Package) is attached to a substrate of a display panel, or a structure in which an IC is mounted on the substrate by a COG (Chip On Glass) method or the like is referred to as a display panel module or a display module, or simply as a display panel or the like in some cases.

### Embodiment 1

In this embodiment, an electronic device of one embodiment of the present invention will be described.

An electronic device of one embodiment of the present invention is an electronic device that can be worn on a head. The electronic device can offer a three-dimensional image using parallax to a user. That is, the electronic device can be used as a VR device. Furthermore, the electronic device may have a function of displaying scenery in front of the user, which is captured with a camera (this function is also referred to as a video see-through function). Moreover, the electronic device can perform what is called AR display in which an image is displayed to overlap with the scenery in front of the user.

The electronic device includes two display devices (a first display device and a second display device) and an eyepiece lens. The user can see an image obtained by synthesizing a first image displayed by the first display device and a second image displayed by the second display device through the eyepiece lens.

More specifically, the electronic device preferably includes a half mirror. One of the first image and the second image passes through the half mirror and reaches the eyepiece lens, and the other image is reflected by the half mirror and reaches the eyepiece lens. The first display device, the second display device, the half mirror, and the eyepiece lens are arranged in the above manner, whereby the user can see, through the eyepiece lens, an image obtained by superimposing (synthesizing) the first image and the second image.

Furthermore, the electronic device preferably includes a lens in addition to the eyepiece lens. The lens is provided between the second display device and the half mirror and has a function of magnifying the second image. Accordingly, an image the user can see is obtained by synthesizing the first image and the magnified second image through the eyepiece lens. At this time, the first image is located at the center, and part of the second image is located to surround the first image.

As the first display device and the second display device, display devices with the same pixel density can be used. At this time, the first image located at the center from the user's viewpoint enables high-resolution display, whereas part of the second image seen outside the first image is magnified by the lens and accordingly displayed as an image with a lower resolution than the first image. In general, human visual performance tends to increase the discrimination ability as an object is closer to the center (gaze point) of the visual field and decreases the discrimination ability as the object is distanced from the gaze point. Thus, even when the user is shown the first image located at the center as a high-resolution image and part of the second image located around the first image as an image with a lower resolution than the first image, the user recognize the above images as a high-resolution image without discomfort.

Here, it is difficult for the display device to achieve both high pixel density and a large screen size. Thus, in the case where one display device with high pixel density is used, it is difficult to increase the viewing angle: a high sense of immersion cannot be obtained even when the resolution is high. The attempt to increase the viewing angle with a lens causes a decrease in the resolution due to magnification as well as the distortion of a screen around an image and the influence of aberration: as a result, the sense of immersion is decreased. By contrast, in the electronic device of one embodiment of the present invention, both high-resolution display and a large viewing angle can be achieved with use of two display devices; thus, the user can obtain an extremely high sense of immersion.

Note that in this specification and the like, the viewing angle of the electronic device refers to a range where the user can see an image through an optical member such as a lens. Furthermore, unless otherwise specified, the description of “viewing angle” denotes the viewing angle in the horizontal direction. Note that the term “viewing angle” includes the viewing angle with one eye and the viewing angle with both eyes, and generally the viewing angle with both eyes is larger than that with one eye. The viewing angle is also referred to as FOV (Field of View) in some cases.

Furthermore, the same product can be used for the first display device and the second display device. Thus, two kinds of display devices are not necessary, and the same kind of display devices can be used for the first display device and the second display device: accordingly, the manufacturing cost of the electronic device can be reduced.

More specific examples of the electronic device are described below with reference to drawings.

### Structure Example 1

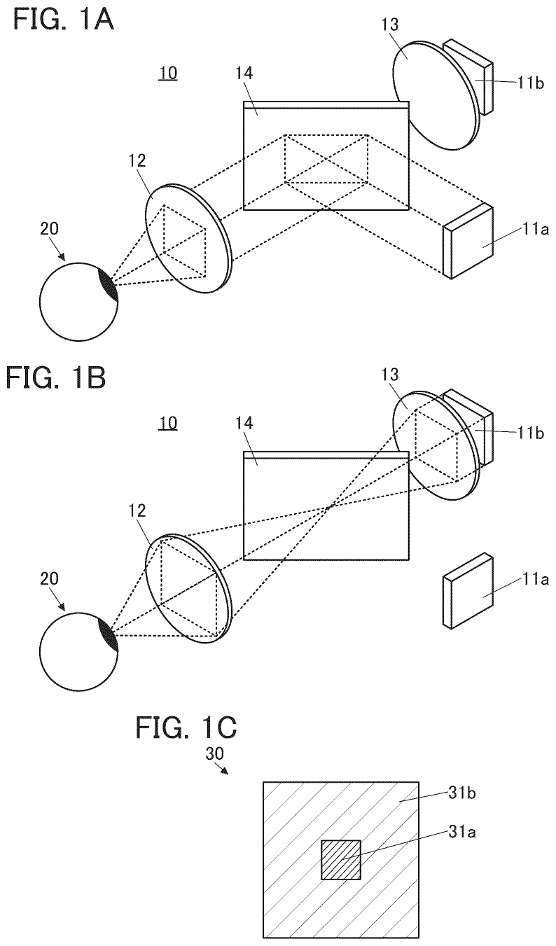

FIG. 1A and FIG. 1B are perspective views each illustrating part of a structure of an electronic device 10 of one embodiment of the present invention. The electronic device 10 includes a display device 11a, a display device 11b, a lens 12, a lens 13, and a half mirror 14. In FIG. 1A and FIG. 1B, an eye 20 of a user in the vicinity of the lens 12 is schematically illustrated.

The display device 11a and the display device 11b each have a function of displaying an image. The display device 11a and the display device 11b preferably have the same structure. Thus, the cost of the electronic device 10 can be reduced as compared with the case of using different kinds of display devices. With use of the display devices with the same structure, a difference in characteristics (such as a color tone, luminance, color reproducibility, and a response speed) between the display device 11a and the display device 11b can be made small. Thus, the correction to match the characteristics is facilitated as compared with the case of using different kinds of display devices.

Display devices at least with the same pixel density can be used as the display device 11a and the display device 11b. For the display device 11a and the display device 11b, it is preferable to use display devices having an equivalence in one or more of the number of pixels, the screen size, the aspect ratio of the screen, the type of display element, the power supply voltage, and the drive frequency (also referred to as frame frequency). It is particularly preferable for the display device 11a and the display device 11b to use display devices manufactured by/at/on the same manufacturer, manufacturing plant, and production line.

Note that for the display device 11a and the display device 11b, display devices between which the layouts of all of the wirings, terminals, drivers (driving circuits), and the like are the same may be used, or display devices between which the layout of one or more of the wirings, the terminals, the drivers (driving circuits), and the like is different may be used.

As the pixel density of each of the display device 11a and the display device 11b, the higher the better. For example, the pixel density can be higher than or equal to 1000 ppi and less than or equal to 20000 ppi, preferably higher than or equal to 2000 ppi and less than or equal to 15000 ppi, further preferably higher than or equal to 3000 ppi and less than or equal to 10000 ppi, still further preferably higher than or equal to 4000 ppi and less than or equal to 9000 ppi, still further preferably higher than or equal to 5000 ppi and less than or equal to 8000 ppi.

As the display portion of each of the display device 11a and the display device 11b is increased, the lens 12 can be made thin, and the image distortion due to the lens can be suppressed. For example, the diagonal size of the display portion of first display device is preferably 0.3 inches or more or 0.5 inches or more, further preferably 0.7 inches or more, still further preferably 1 inch or more, yet further preferably 1.3 inches or more, and 2 inches or less or 1.7 inches or less. Specifically, 1.5 inches or a similar size is preferable.

The diagonal of the display portion of each of the display device 11a and the display device 11b is preferably smaller than the diameter of the lens 12. For example, the diagonal of the display portion of the display device 11a or the display device 11b is preferably 90% or less, preferably 80% or less, further preferably 70% or less of the diameter of the lens 12. Thus, the distortion of an image that can be seen through the lens 12 can be made small, increasing the sense of immersion. If the diagonal of the display portion of the each of the display device 11a and the display device 11b is larger than the diameter of the lens 12, part of the display portion might be out of the visual field.

The diagonal of the display portion of the display device 11b is preferably smaller than the diameter of the lens 13. For example, the diagonal of the display portion of the display device 11b can be 90% or less, preferably 80% or less, further preferably 70% or less of the diameter of the lens 13. Thus, the distortion of an image that can be seen through the lens 12 can be made small, increasing the sense of immersion. If the diagonal of the display portion of the display device 11b is larger than the diameter of the lens 13, part of the display portion might be out of the visual field.

Note that the pixel density and the size of the display portion in each of the display device 11a and the display device 11b are not limited to the above. For example, in the case where a high resolution is not required, a display device having a pixel density lower than 1000 ppi may be used, or a display device having a diagonal size longer than 2 inches can be used.

The lens 12 is a lens located closest to the eye 20 side and can also be referred to as an eyepiece lens. A convex lens is preferably used as the lens 12.

The lens 13 has a function of magnifying an image displayed on the display device 11b in combination with the lens 12. One convex lens can be used as the lens 13, for example. Note that the lens 13 is not limited thereto and may have a structure including one or more of a concave lens and a convex lens or a structure including both the concave lens and the convex lens. Note that it is preferable for the lens 13 to achieve a function of magnifying an image displayed on the display device 11b, and another optical member, without limiting to a lens, utilizing characteristics such as light reflection, refraction, polarization, diffraction, or scattering may be used.

The half mirror 14 is an optical member having both a reflective property and a transmitting property with respect to visible light. For example, an optical member in which a thin metal film or a dielectric multilayer film is formed on a transparent base such as glass, quartz, resin, or the like can be used. For the half mirror 14, an optical member whose ratio of transmittance to reflectance is 1:1 is preferably used. Since light from the display device 11b is magnified by the lens 13, in order to inhibit a reduction in luminance seen from the user, an optical member where the proportion of transmittance is higher than that of reflectance may be used for the half mirror 14. As long as the half mirror 14 achieves a function of synthesizing two images, another optical member, without limiting to a half mirror, utilizing characteristics such as light reflection, refraction, polarization, diffraction, or scattering may be used.

In FIG. 1A, tracks of light (image) emitted by the display device 11a are denoted by dotted lines. The image of the display device 11a is reflected by the half mirror 14 and reaches the eye 20 through the lens 12. The user sees an image in such a state that the image displayed on the display device 11a is magnified through the lens 12.

In FIG. 1B, tracks of light emitted by the display device 11b are denoted by dotted lines. An image of the display device 11b passes through the lens 13 and the half mirror and reaches the lens 12. The user sees an image in such a state that the image displayed on the display device 11b is further magnified through the lens 12.

FIG. 1C schematically illustrates an image 30 that can be seen by the user through the lens 12 when the display device 11a and the display device 11b are concurrently made to display images. The image 30 includes a region 31a located at the center and a region 31b located outside the region 31a. The region 31a is a portion displayed by the display device 11a, and the region 31b is a portion displayed by the display device 11b. The region 31a has a higher resolution than the region 31b.

The image displayed by the display device 11a and the image displayed by the display device 11b are synthesized by the half mirror 14. Therefore, it is important to adjust images displayed on the display device 11a and the display device 11b so that a region where two different images overlap with each other does not appear. For example, the display device 11b can be adjusted so that the image in a region overlapping with the region 31a is not displayed (i.e., black display is performed in such a region). Alternatively, an image with a resolution downsized from that of an image displayed on the region 31a of the display device 11a is displayed at the center portion of the display device 11b (the center portion is located in the region 31a), so that an image with a high resolution, which is from the display device 11a, and the image with a low resolution, which is from the display device 11b, may overlap and be displayed in the region 31a.

In general, the human visual field is roughly classified into the following five fields, although varying between individuals. The discrimination visual field refers to a region within approximately 5° from the center of vision including the gaze point, where visual performance such as eyesight and color identification is the most excellent. The effective visual field refers to a region that is horizontally within approximately 30° and vertically within approximately 20° from the center of vision (gaze point) and adjacent to the outside of the discrimination visual field, where instant identification of particular information is possible only with an eye movement. The stable visual field refers to a region that is horizontally within approximately 90° and vertically within approximately 70° from the center of vision and adjacent to the outside of the effective visual field, where identification of particular information is possible without any difficulty with a head movement. The inducting visual field refers to a region that is horizontally within approximately 100° and vertically within approximately 85° from the center of vision and adjacent to the outside of the stable visual field, where the existence of a particular target can be sensed but the identification ability is low. The supplementary visual field refers to a region that is horizontally within approximately 100° to 200° and vertically within approximately 85° to 130° from the center of vision and adjacent to the outside of the inducting visual field, where the identification ability for a particular target is significantly low to an extent that the existence of a stimulus can be sensed.

Thus, the region 31a preferably provides a viewing angle within at least where the discrimination visual field falls. More specifically, the region 31a preferably provides a viewing angle greater than or equal to 5° and less than or equal to 30° in the horizontal direction. The region 31b preferably provides a viewing angle that covers the supplementary visual field because the sense of immersion is increased as the viewing angle is enlarged. More specifically, the region 31b preferably provides a viewing angle greater than the viewing angle of the region 31a and less than or equal to 220° in the horizontal direction.

Note that in this specification and the like, unless otherwise specified, the description of “viewing angle” denotes the viewing angle in the horizontal direction.

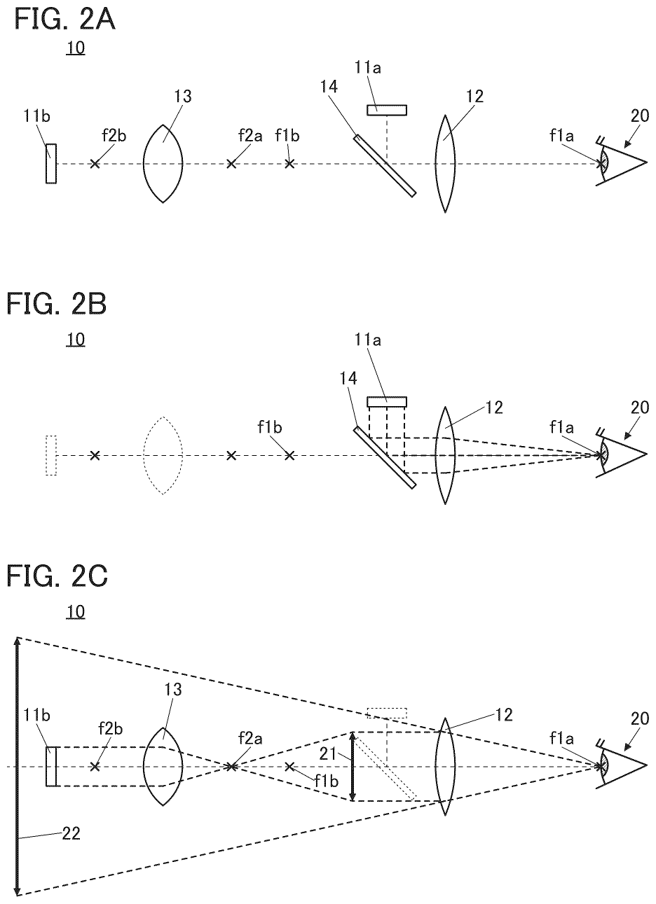

Next, a specific structure of the electronic device 10 is described. FIG. 2A is a schematic view of the electronic device 10. FIG. 2A is a schematic view seen in the direction perpendicular to the optical axes of the lens 13 and the lens 12.

The lens 12 and the lens 13 are provided so that their optical axes are aligned with each other. The display device 11b is provided on the optical axes. The half mirror 14 is provided between the lens 12 and the lens 13. An example shown here is such that the half mirror 14 is provided at an angle of 45° to the optical axis of the lens 12 and the display device 11a is provided at an angle of 45° to the reflective surface of the half mirror 14. Note that the angle of the half mirror 14 or the like is not limited thereto.

The focus of the lens 12 on the eye 20 side is referred to as a focus f1a, and the focus of the lens 12 on the opposite side is referred to as a focus f1b. An example in which the eye 20 is located at the focus f1a is shown here.

The display device 11a is preferably located so that the distance of a path from the display surface of the display device 11a to the center of the lens 12 via the reflective surface of the half mirror 14 is shorter than the focal length of the lens 12.

FIG. 2B illustrates a diagram focusing on the display device 11a. Light (denoted by dashed lines) coming perpendicularly from the display surface of the display device 11a is reflected by the half mirror 14 and reaches the lens 12. The light is condensed by the lens 12 and reaches the eye 20. The user sees an image in such a state that the image displayed on the display device 11a is magnified through the lens 12.

Here, the image that can be seen by the eye 20 is an image inverted horizontally or vertically, by the half mirror 14, from the image displayed on the display portion of the display device 11a. Thus, it is preferable to display an image that is inverted horizontally or vertically beforehand on the display device 11a.

Next, the focus of the lens 13 on the eye 20 side is referred to as a focus f2a, and the focus of the lens 13 on the opposite side is referred to as f2b. The display device 11b is provided outside the focus f2b.

FIG. 2C illustrates a diagram focusing on the display device 11b. Light (denoted by dashed lines) coming from the display surface of the display device 11b is refracted by the lens 13 and an image 21 is formed at a position far from the focus f2a. At this time, the lens 13 and the display device 11b are provided so that the position where the image 21 is formed is located between the lens 12 and the focus f1b. The user can see an image 22 that is obtained by further magnifying the image 21 through the lens 12.

Here, the image 21 is an inverted image (real image), and the image 22 is the magnified image 21: thus, the image seen by the eye 20 is an image inverted horizontally or vertically from the image displayed on the display portion of the display device 11b. Hence, it is preferable to display an image that is inverted horizontally or vertically beforehand on the display device 11b.

### [Example of Image]

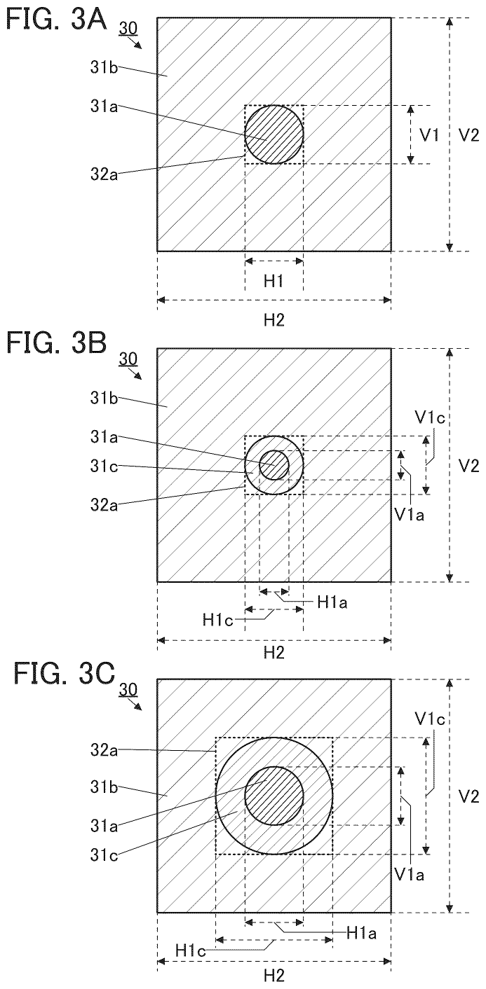

Next, examples of the image 30 that can be shown to the user by the electronic device 10 are described. FIG. 3A to FIG. 3C illustrate examples of the image 30.

FIG. 3A illustrates the region 31a with a high resolution and the region 31b with a lower resolution than the region 31a. An example shown here is the case where the region 31a is displayed to have a circular shape. A region 32a of the display device 11a is denoted by a dashed line in this example.

As illustrated in FIG. 3A, even when the shape of the region 32a of the display device 11a is a rectangle, the region 31a can be made in another shape. At this time, the outside of the circular image is made in a non-display (black display) state in the display device 11a, and the image of the display device 11b is made to overlap with the non-display portion, so that the seamless image 30 can be displayed.

Note that although the outline of the region 31b is shown as a rectangle here, the outline may have a curved shape when an image through the lens 12 or the like is distorted. The outline of an image displayed on the display device 11b may be an image in a shape other than a rectangle.

Here, the viewing angle of the region 31a in the horizontal direction is H1 and the viewing angle thereof in the perpendicular direction is V1. The viewing angle of the region 31b in the horizontal direction is H2, and the viewing angle thereof in the perpendicular direction is V2. H2 is larger than H1, and V2 is larger than V1.

Although the region 31a is illustrated in a circular shape in FIG. 3A, it is not limited thereto: a rectangular shape, a polygonal shape that has five or more vertices, or an elliptical shape may be employed. Alternatively, a shape surrounded by an arbitrary curve or a shape surrounded by a curve and a straight line, such as a quadrangular shape with rounded corners, can be used.

In the case where the region 31a has a shape other than a circular shape and a square shape, the viewing angle H1 in the horizontal direction is preferably larger than the viewing angle V1 in the vertical direction. For example, an elliptical shape whose major axis is parallel to the horizontal direction can be employed. In this case, the ratio of the major axis to the minor axis is higher than or equal to 110%, preferably higher than or equal to 120%, further preferably higher than or equal to 130% and lower than or equal to 180%, still further preferably lower than or equal to 170%, and yet still further preferably lower than or equal to 160%. The human visual field is not completely circular symmetric but a horizontal shape: thus, when the region 31a is in such a shape, an electronic device that is less likely to give discomfort can be achieved.

In FIG. 3B, a region 31c is provided between the region 31a and the region 31b. The region 31c is located on the inner side of the region 32a and has a lower resolution than the region 31a and has a higher resolution than the region 31b. The images displayed on the region 31a and the region 31b is an image displayed by the display device 11a.

Here, the viewing angle of the region 31a in the horizontal direction is H1a, the viewing angle thereof in the perpendicular direction is V1a, the viewing angle of the region 31c in the horizontal direction is H1c, and the viewing angle thereof in the perpendicular direction is V1c. H1c is larger than H1a, and V1c is larger than V1a.

FIG. 3C shows an example in which the difference in the magnification rates of two images is made smaller than that in FIG. 3B. The example shown in FIG. 3C is the case where the magnification rates of the images are adjusted so that H1c is 50% of H2 and V1c is 50% of V2.

The outlines of the region 31a and the region 31c in FIG. 3B and FIG. 3C are not limited to a circular shape. For the other shapes, the above description of the region 31a can be referred to.

### Structure Example 2

Other structure examples of the electronic device 10 are described below.

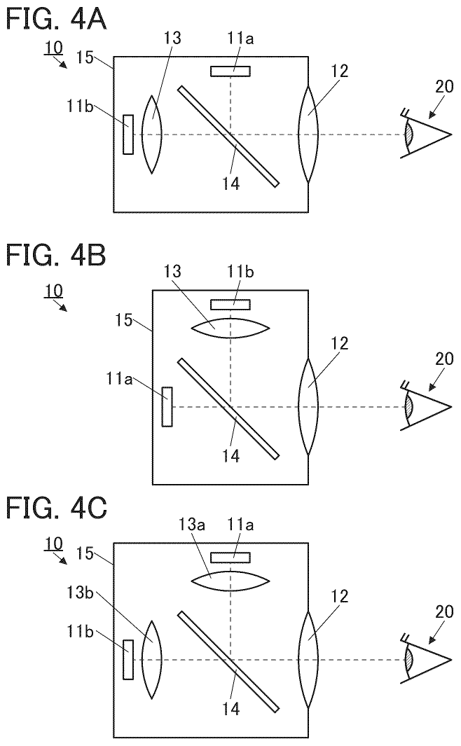

The electronic device 10 illustrated in FIG. 4A includes a housing 15, and the display device 11a, the display device 11b, the lens 13, the half mirror 14, and the like are provided in the housing 15. The lens 12 functioning as an eyepieces lens is provided to be exposed from the housing 15. The user can wear the housing 15 on the his/her head and can see images through the lens 12.

FIG. 4B illustrates an example in which the positions of the display device 11a and the display device 11b are changed. That is, the image of the display device 11a passes through the half mirror 14 and reaches the lens 12. On the other hand, the image of the display device 11b passes through the lens 13, is reflected by the half mirror 14, and reaches the lens 12.

In this case, an optical member where the proportion of reflectance is higher than that of transmittance may be used for the half mirror 14.

FIG. 4C illustrates an example in which a lens 13a and a lens 13b are provided on an optical path of the display device 11a and an optical path of the display device 11b, respectively. In this case, it is preferable to arrange the components so that the rate of magnification by the lens 13a and the rate of magnification by the lens 13b differ from each other. Specifically, it is possible to select the lens 13a and the lens 13b such that the rate of magnification by the lens 13a is higher than that by the lens 13b or such that the rate of magnification by the lens 13b is higher than that by the lens 13a.

### Variation Example 1

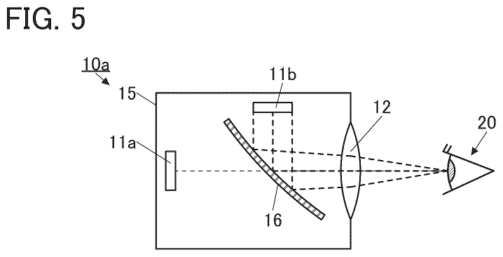

FIG. 5 illustrates an example of an electronic device 10a including a half mirror 16 having a curved surface instead of the half mirror 14. The half mirror 16 functions as a concave mirror when seen from the display device 11b, and thus has a function of magnifying the image of the display device 11b.

With such a structure, the half mirror 16 can also serve as the lens 13. The number of components of the electronic device 10a can be reduced. Moreover, the electronic device 10a can be made lighter in weight.

### Variation Example 2

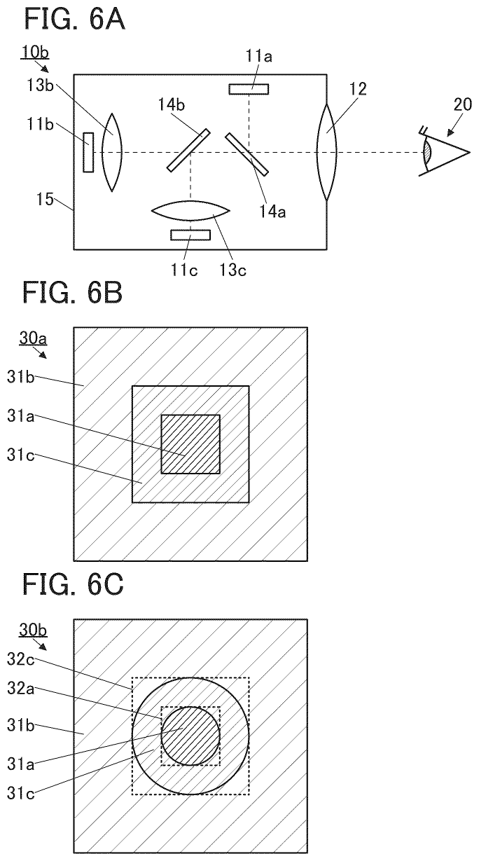

FIG. 6A illustrates an electronic device 10b having a structure different from the above. The electronic device 10b is different from the electronic device 10 illustrated in FIG. 4A mainly in including a display device 11c, a lens 13c, and a half mirror 14b, and using a half mirror 14a instead of the half mirror 14.

The image of the display device 11c passes through the lens 13c, is reflected by the half mirror 14b, passes through the half mirror 14a, and reaches the lens 12. The user can see an image magnified by the lens 13c and the lens 12.

The electronic device 10b illustrated in FIG. 6A can show an image obtained by synthesizing three images displayed by three display devices. Although the structure including three display devices is described here, a structure including four or more display devices may be employed.

FIG. 6B illustrates an example of an image 30a the user can see with the electronic device 10b. The image 30a includes the region 31a located at the center, the region 31b, and a region 31c between the region 31a and the region 31b. The region 31c has a lower resolution than the region 31a and higher resolution than the region 31b.

FIG. 6C illustrates an example of an image 30b in the case where the outlines of the region 31a and the region 31c are circular. In FIG. 6C, the region 32a corresponding to a display region of the display device 11a and a region 32c corresponding to a display region of the display device 11c are denoted by dashed lines.

The above is the description of the variation examples.

### Structure Example 3

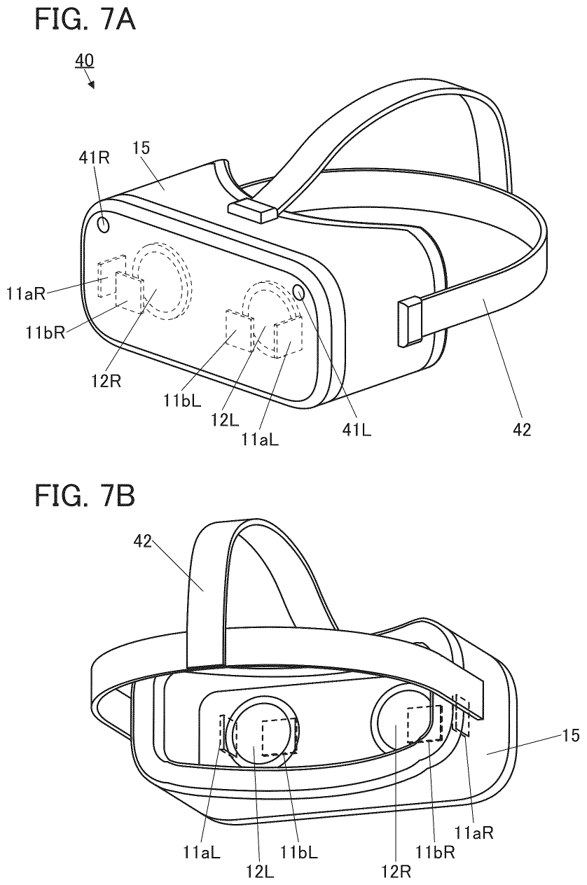

FIG. 7A and FIG. 7B illustrate perspective views of an electronic device 40. The perspective view of FIG. 7A shows the front surface, the top surface, and the left side surface of the electronic device 40, and the perspective view of FIG. 7B illustrates the back surface, the bottom surface, and the right side surface of the electronic device 40. The electronic device 40 is what is called a goggle-type head mounted display (HMD), which can be worn on the head. The electronic device 40 can be used as an electronic device for VR, for example. The user wearing the electronic device 40 can watch a three-dimensional video using parallax with different videos for the right eye and the left eye.

The electronic device 40 includes a housing 15 and a wearing tool 42. The wearing tool 42 has a function of fixing the housing 15 to the head.

A camera 41R and a camera 41L are provided on the surface of the housing 15. A video taken with the camera 41R and the camera 41L is displayed in real time, whereby the user can know the user's surroundings even when the user is wearing the electronic device 40. Furthermore, a video see-through function can be achieved. A three-dimensional video using parallax can be produced with two or more cameras.

On the side of the housing 15 facing the user, a lens 12R functioning as an eyepiece lens for a right eye and a lens 12L functioning as an eyepiece lens for a left eye are provided in portions to be in front of the user's eyes. Furthermore, a display device 11aR and a display device 11bR for displaying an image for the right eye and a display device 11aL and a display device 11bL for displaying an image for the left eye are provided inside the housing 15. Note that various optical systems given above can be employed: thus, components such as a half mirror and a lens are omitted here.

When the relative position of the display device 11aR and the display device 11bR is shifted, an image is distorted. Thus, the display device 11aR and the display device 11bR are fixed to the same frame so that their relative position is not shifted by impact or the like. The same applies to the display apparatus 11aL and the display apparatus 11bL. Meanwhile, the display device 11aR and the display device 11aL are preferably configured to move up and down, forward and backward, and left and right in accordance with the positions of the user's eyes, for example. Thus, the display device 11aR and the display device 11aL may be fixed to separate frames.

An input terminal and an output terminal may be provided on the surface of the housing 15. To the input terminal, a cable for supplying a video signal from a video output device or the like, power for charging a battery provided in the housing 15, or the like can be connected. Examples of the output terminal include terminals functioning as, for example, an audio output terminal to which earphones, headphones, or the like can be connected. Note that in the case where audio data can be output by wireless communication or sound is output from an external video output device, the audio output terminal is not necessarily provided.

A wireless communication module, a memory module, and the like may be provided inside the housing 15. A content to be watched can be downloaded via wireless communication using the wireless communication module and stored in the memory module. In this manner, the user can watch the downloaded content offline whenever the user likes.

At least part of this embodiment can be implemented in appropriate combination with the other embodiments described in this specification.

### Embodiment 2

In this embodiment, structure examples of a display device that can be employed for the electronic device of one embodiment of the present invention will be described. A display device described below as an example can be employed for the display device 11a, the display device 11b, and the like in Embodiment 1.

One embodiment of the present invention is a display device including a light-emitting element (also referred to as a light-emitting device). The display device includes two or more light-emitting elements of different emission colors. Each of the pixels includes a light-emitting element. The light-emitting elements each include a pair of electrodes and an EL layer therebetween. The light-emitting elements are preferably organic EL elements (organic electroluminescent elements). The two or more light-emitting elements of different emission colors include EL layers formed using different light-emitting materials. For example, when three kinds of light-emitting elements that emit red (R), green (G), and blue (B) light are included, a full-color display device can be achieved.

In the case of manufacturing a display device including a plurality of light-emitting elements that emit light of different emission colors, layers (light-emitting layers) containing at least light-emitting materials of different emission colors each need to be formed in an island shape. In the case of separately forming part or the whole of an EL layer, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a deposited film due to vapor scattering, for example: accordingly, it is difficult to achieve a high resolution and a high aperture ratio of the display device. In addition, the outline of the layer might blur during evaporation, so that the thickness of an end portion might be reduced. That is, the thickness of an island-shaped light-emitting layer might vary from place to place. In addition, in the case of manufacturing a display device with a large size, high definition, or high resolution, a manufacturing yield might be reduced because of low dimensional accuracy of the metal mask and deformation due to heat or the like. Thus, a measure has been taken for a pseudo increase in resolution (also referred to as pixel density) by employing a unique pixel arrangement such as a PenTile arrangement.

Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

In one embodiment of the present invention, fine patterning of EL layers is performed by photolithography without using a shadow mask such as a fine metal mask (an FMM). Accordingly, it is possible to achieve a display device with high resolution and a high aperture ratio, which has been difficult to achieve. Moreover, since the EL layers can be formed separately, it is possible to achieve a display device that performs extremely clear display with high contrast and high display quality. Note that fine patterning of the EL layers may be performed using both a metal mask and photolithography, for example.

In addition, part or the whole of an EL layer can be physically divided. This can inhibit leakage current flowing between adjacent light-emitting elements through a layer (also referred to as a common layer) shared by the light-emitting elements. This can prevent crosstalk due to unintended light emission, so that a display device with extremely high contrast can be achieved. In particular, a display device having high current efficiency at low luminance can be achieved.

In one embodiment of the present invention, the display device can be also obtained by combining a light-emitting element that emits white light with a color filter. In that case, light-emitting elements having the same structure can be employed as light-emitting elements provided in pixels (subpixels) that emit light of different colors, which allows all the layers to be common layers. In addition, part or the whole of each EL layer is divided by photolithography. Thus, leakage current through the common layer is suppressed: accordingly, a high-contrast display device can be achieved. In particular, when an element has a tandem structure in which a plurality of light-emitting layers are stacked with a highly conductive intermediate layer therebetween, leakage current through the intermediate layer can be effectively prevented, so that a display device with high luminance, high resolution, and high contrast can be achieved.

In the case where the EL layer is processed by a photolithography method, part of the light-emitting layer is sometimes exposed to cause deterioration. Thus, an insulating layer covering at least a side surface of the island-shaped light-emitting layer is preferably provided. The insulating layer may cover part of a top surface of an island-shaped EL layer. For the insulating layer, a material having a barrier property against water and oxygen is preferably used. For example, an inorganic insulating film in which water or oxygen is less likely to diffuse can be used. This can inhibit degradation of the EL layer and can achieve a highly reliable display device.

Moreover, between two adjacent light-emitting elements, there is a region (a depressed portion) where none of the EL layers of the light-emitting elements is provided. In the case where a common electrode or a common electrode and a common layer are formed to cover the depressed portion, a phenomenon where the common electrode is divided by a step at an end portion of the EL layer (such a phenomenon is also referred to as disconnection) might occur, which might cause insulation of the common electrode over the EL layer. In view of this, a local gap positioned between two adjacent light-emitting elements is preferably filled with a resin layer functioning as a planarization film (also referred to as LFP: Local Filling Planarization). The resin layer has a function of the planarization film. This structure can inhibit disconnection of the common layer or the common electrode and can achieve a highly reliable display device.

More specific structure examples of the display device of one embodiment of the present invention will be described below with reference to drawings.

### Structure Example 1

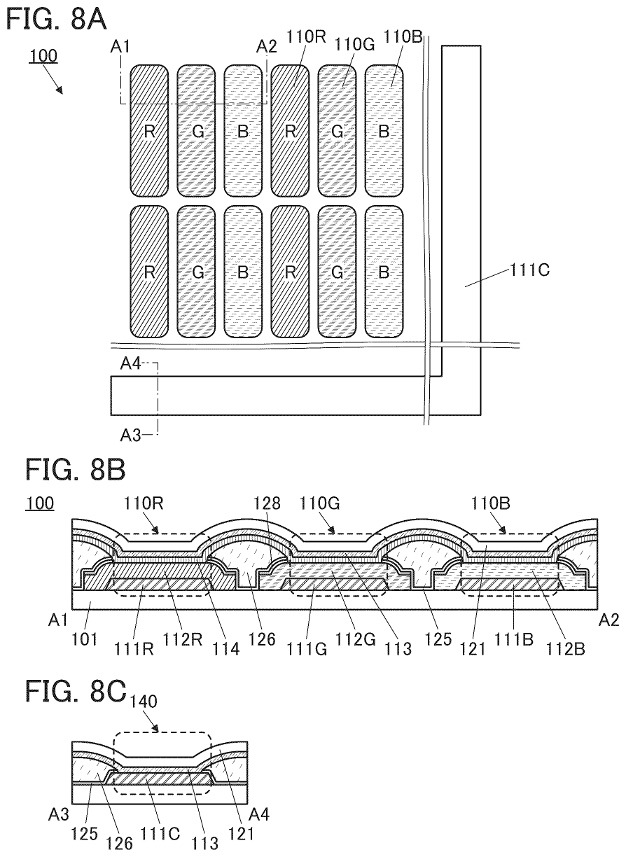

FIG. 8A illustrates a schematic top view of a display device 100 of one embodiment of the present invention. The display device 100 includes, over a substrate 101, a plurality of light-emitting elements 110R exhibiting red, a plurality of light-emitting elements 110G exhibiting green, and a plurality of light-emitting elements 110B exhibiting blue. In FIG. 8A, light-emitting regions of the light-emitting elements are denoted by R. G, and B to easily differentiate the light-emitting elements.

The light-emitting elements 110R, the light-emitting elements 110G, and the light-emitting elements 110B are arranged in a matrix. FIG. 8A illustrates what is called a stripe arrangement, in which the light-emitting elements of the same color are arranged in one direction. Note that an arrangement method of the light-emitting elements is not limited thereto: an arrangement method such as an S-stripe arrangement, a delta arrangement, a Bayer arrangement, or a zigzag arrangement may be employed, or a PenTile arrangement, a diamond arrangement, or the like can be also used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. As examples of a light-emitting substance contained in the EL element, a substance that emits fluorescent light (a fluorescent material), a substance that emits phosphorescent light (a phosphorescent material), and a substance that exhibits thermally activated delayed fluorescence (a thermally activated delayed fluorescent (TADF) material) can be given. As the light-emitting substance contained in the EL element, not only an organic compound but also an inorganic compound (a quantum dot material or the like) can be used.

FIG. 8A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region or may be provided along two or more sides of the outer periphery of the display region. That is, in the case where the display region has a rectangular top surface shape, a top surface shape of the connection electrode 111C can have a band shape (a rectangle), an L shape, a U shape (a square bracket shape), a quadrangular shape, or the like. Note that in this specification and the like, the top surface shape of a component means the outline of the component in a plan view. A plan view means a view to observe the component from a normal direction of a surface where the component is formed or from a normal direction of a surface of a support (e.g., a substrate) where the component is formed.

FIG. 8B and FIG. 8C are schematic cross-sectional views corresponding to the dashed-dotted line A1-A2 and the dashed-dotted line A3-A4 in FIG. 8A. FIG. 8B illustrates a schematic cross-sectional view of the light-emitting element 110R, the light-emitting element 110G, and the light-emitting element 110B, and FIG. 8C illustrates a schematic cross-sectional view of a connection portion 140 where the connection electrode 111C and the common electrode 113 are connected to each other.

The light-emitting element 110R includes a pixel electrode 111R, an organic layer 112R, a common layer 114, and the common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R includes at least a light-emitting organic compound that emits red light. The organic layer 112G included in the light-emitting element 110G includes at least a light-emitting organic compound that emits green light. The organic layer 112B included in the light-emitting element 110B includes at least a light-emitting organic compound that emits blue light. Each of the organic layer 112R, the organic layer 112G, and the organic layer 112B can be also referred to as an EL layer and includes at least a layer containing a light-emitting organic compound (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure in which the organic layer 112 includes a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. In addition, the common electrode 113 and the common layer 114 are each provided as a continuous layer shared by the light-emitting elements. A conductive film having a property of transmitting visible light is used for either the pixel electrodes or the common electrode 113, and a conductive film having a reflective property is used for the other. When the pixel electrodes have a light-transmitting property and the common electrode 113 has a reflective property, a bottom-emission display device can be obtained. In contrast, when the pixel electrodes have a reflective property and the common electrode 113 has a light-transmitting property, a top-emission display device can be obtained. Note that when both the pixel electrodes and the common electrode 113 have a light-transmitting property, a dual-emission display device can be also obtained.

A protective layer 121 is provided over the common electrode 113 to cover the light-emitting element 110R, the light-emitting element 110G, and the light-emitting element 110B. The protective layer 121 has a function of preventing diffusion of impurities such as water into each light-emitting element from the above.

An end portion of the pixel electrode 111 preferably has a tapered shape. In the case where the pixel electrode 111 has an end portion with a tapered shape, the organic layer 112 that is provided along the end portion of the pixel electrode 111 can also have a tapered shape. When the end surface of the pixel electrode 111 has a tapered shape, coverage with the organic layer 112 provided beyond the end portion of the pixel electrode 111 can be improved. Furthermore, when the side surface of the pixel electrode 111 has a tapered shape, a foreign matter (also referred to as dust or particles) in the manufacturing process is easily removed by processing such as cleaning, which is preferable.

Note that in this specification and the like, a tapered shape refers to a shape such that at least part of a side surface of a component is inclined to a substrate surface. For example, a tapered shape preferably includes a region where the angle between the inclined side surface and the substrate surface (such an angle is also referred to as a taper angle) is less than 90°.

The organic layer 112 is processed into an island shape by a photolithography method. Thus, an angle formed between a top surface and a side surface of an end portion of the organic layer 112 is approximately 90°. By contrast, an organic film formed using an FMM (Fine Metal Mask) or the like has a thickness that tends to gradually decrease with decreasing distance to an end portion, and has a top surface forming a slope in an area extending greater than or equal to 1 μm and less than or equal to 10 μm to the end portion, for example: thus, such an organic film has a shape whose top surface and side surface are difficult to distinguish from each other.

An insulating layer 125, a resin layer 126, and a layer 128 are included between two adjacent light-emitting elements.

Between two adjacent light-emitting elements, side surfaces of the organic layers 112 are provided to face each other with the resin layer 126 therebetween. The resin layer 126 is positioned between the two adjacent light-emitting elements and is provided to bury end portions of the organic layers 112 and a region between the two organic layers 112. The resin layer 126 has a top surface with a smooth convex shape. The common layer 114 and the common electrode 113 are provided to cover the top surface of the resin layer 126.

The resin layer 126 functions as a planarization film that fills a step positioned between two adjacent light-emitting elements. Providing the resin layer 126 can prevent a phenomenon in which the common electrode 113 is divided by a step at an end portion of the organic layer 112 (such a phenomenon is also referred to as disconnection) from occurring and the common electrode over the organic layer 112 from being insulated. The resin layer 126 can also be referred to as an LFP (Local Filling Planarization) layer.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used as the photosensitive resin. As the photosensitive resin, a positive material or a negative material can be used.

The resin layer 126 may contain a material absorbing visible light. For example, the resin layer 126 itself may be made of a material absorbing visible light, or the resin layer 126 may contain a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surfaces of the organic layers 112. In addition, the insulating layer 125 is provided to cover an upper end portion of the organic layer 112. Furthermore, part of the insulating layer 125 is provided in contact with the top surface of the substrate 101.

The insulating layer 125 is positioned between the resin layer 126 and the organic layer 112 and functions as a protective film for preventing contact between the resin layer 126 and the organic layer 112. When the organic layer 112 and the resin layer 126 are in contact with each other, the organic layer 112 might be dissolved by an organic solvent or the like used at the time of forming the resin layer 126. Therefore, the insulating layer 125 is provided between the organic layer 112 and the resin layer 126, whereby the side surfaces of the organic layer 112 can be protected.

An insulating layer containing an inorganic material can be used for the insulating layer 125. For the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is employed for the insulating layer 125, it is possible to form the insulating layer 125 that has a small number of pinholes and has an excellent function of protecting the EL layer.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The insulating layer 125 can be formed by a sputtering method, a CVD method, a PLD method, an ALD method, or the like. The insulating layer 125 is preferably formed by an ALD method with excellent coverage.

In addition, a structure may be employed in which a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 can have, for example, a single-layer structure or a stacked-layer structure including at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked-layer film of an inorganic insulating film and an organic insulating film can also be used. For example, a structure in which an organic insulating film is sandwiched between a pair of inorganic insulating films is preferable. Furthermore, the organic insulating film preferably functions as a planarization film. This enables a top surface of the organic insulating film to be flat, which results in improved coverage with the inorganic insulating film thereover and a higher barrier property. Moreover, the top surface of the protective layer 121 is flat: therefore, when a component (e.g., a color filter, an electrode of a touch sensor, a lens array, or the like) is provided above the protective layer 121, the component can be less affected by an uneven shape caused by a lower structure.

FIG. 8C illustrates the connection portion 140 where the connection electrode 111C and the common electrode 113 are electrically connected to each other. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 8C illustrates the connection portion 140 where the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, the common layer 114 can be formed to be thin using a material with sufficiently low electrical resistivity: thus, problems do not arise in many cases even when the common layer 114 is located in the connection portion 140. Accordingly, the common electrode 113 and the common layer 114 can be formed using the same shielding mask, so that manufacturing cost can be reduced.

### Structure Example 2

A structure example of a display device whose structure is partly different from that of the above-described Structure Example 1 is described below. Note that the above description can be referred to for portions common to the above-described Structure Example 1, and the repeated description is skipped in some cases.

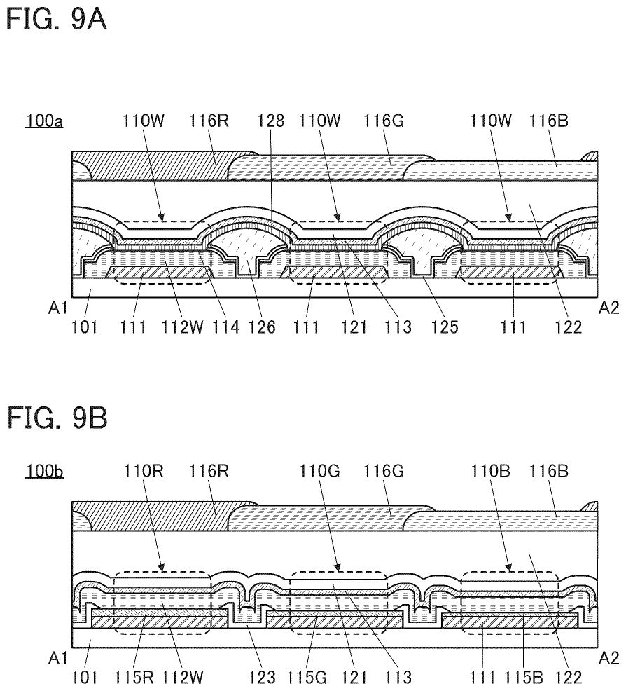

FIG. 9A illustrates a schematic cross-sectional view of a display device 100a. The display device 100a is different from the above-described display device 100 mainly in a structure of the light-emitting element and including a coloring layer.

The display device 100a includes a light-emitting element 110W emitting white light. The light-emitting element 110W includes the pixel electrode 111, an organic layer 112W, the common layer 114, and the common electrode 113. The organic layer 112W emits white light. For example, the organic layer 112W can contain two or more kinds of light-emitting materials emitting light of complementary colors. For example, the organic layer 112W can contain a light-emitting organic compound emitting red light, a light-emitting organic compound emitting green light, and a light-emitting organic compound emitting blue light. Alternatively, the organic layer 112W may contain a light-emitting organic compound emitting blue light and a light-emitting organic compound emitting yellow light.

The organic layer 112W is divided between the two adjacent light-emitting elements 100W. Thus, a leakage current that might flow between the adjacent light-emitting elements 100W through the organic layer 112W can be inhibited and crosstalk due to the leakage current can be inhibited. Accordingly, the display device can have high contrast and high color reproducibility.

An insulating layer 122 functioning as a planarization film is provided over the protective layer 121, and a coloring layer 116R, a coloring layer 116G, and a coloring layer 116B are provided over the insulating layer 122.

An organic resin film or an inorganic insulating film with a flat top surface can be used as the insulating layer 122. The insulating layer 122 is a formation surface on which the coloring layer 116R, the coloring layer 116G, and the coloring layer 116B are formed. Thus, with a flat top surface of the insulating layer 122, the thickness of the coloring layer 116R or the like can be uniform and color purity of light can be increased. Note that if the thickness of the coloring layer 116R or the like is not uniform, the amount of light absorption varies depending on a region in the coloring layer 116R, which might decrease color purity of light.

### Structure Example 3

FIG. 9B illustrates a schematic cross-sectional view of a display device 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 110B includes the pixel electrode 111, a conductive layer 115B, the organic layer 112W, and the common electrode 113. The conductive layer 115R, the conductive layer 115G, and the conductive layer 115B each have a light-transmitting property and function as an optical adjustment layer.

A film reflecting visible light is used for the pixel electrode 111 and a film having both properties of reflecting and transmitting visible light is used for the common electrode 113, whereby a microcavity structure can be obtained. At this time, by adjusting the thicknesses of the conductive layer 115R, the conductive layer 115G, and the conductive layer 115B to obtain optimal optical path lengths, light obtained from the light-emitting element 110R, the light-emitting element 110G, and the light-emitting element 110B can be intensified light with different wavelengths even in the case where the organic layer 112 exhibiting white light emission is used. Furthermore, a coloring layer 116R, a coloring layer 116G, and a coloring layer 116B are provided on the optical paths of the light-emitting element 110R, the light-emitting element 110G, and the light-emitting element 110B, respectively, whereby light with high color purity can be obtained.

An insulating layer 123 that covers an end portion of the pixel electrode 111 and an end portion of an optical adjustment layer 115 is provided. An end portion of the insulating layer 123 preferably has a tapered shape. The insulating layer 123 can increase coverage with the organic layer 112W, the common electrode 113, the protective layer 121, and the like provided over the insulating layer 123.

The organic layer 112W and the common electrode 113 are each provided as one continuous film shared by the light-emitting elements. Such a structure is preferable because the manufacturing process of the display device can be greatly simplified.

Here, the end portion of the pixel electrode 111 is preferably substantially perpendicular. In this manner, a steep portion can be formed on the surface of the insulating layer 123, and thus part of the organic layer 112W covering the steep portion can have a small thickness or part of the organic layer 112W can be separated. Accordingly, a leakage current generated between adjacent light-emitting elements through the organic layer 112W can be inhibited without processing the organic layer 112W by a photolithography method or the like.

The above is the description of the structure example of the display device.

### [Pixel Layout]

Pixel layout different from that in FIG. 8A is mainly described below. There is no particular limitation on the arrangement of light-emitting elements (subpixels), and a variety of methods can be employed.

In addition, examples of a top surface shape of the subpixel include polygons such as a triangle, a tetragon (including a rectangle and a square), and a pentagon: polygons with rounded corners: an ellipse; and a circle. Here, the top surface shape of the subpixel corresponds to a top surface shape of a light-emitting region of the light-emitting element.

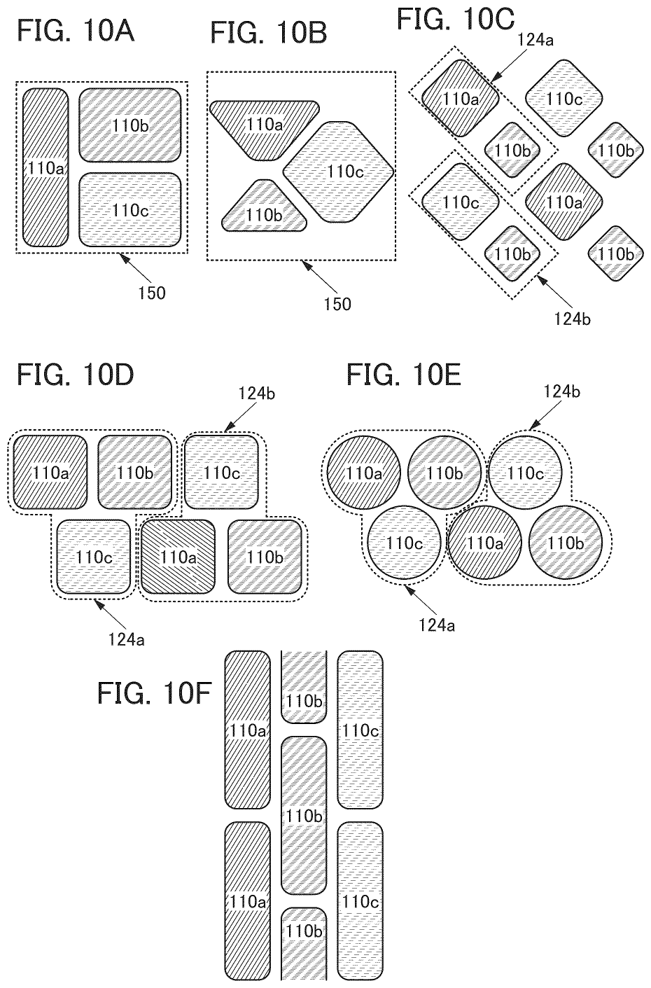

The pixel 150 illustrated in FIG. 10A employs S-stripe arrangement. The pixel 150 illustrated in FIG. 10A is composed of three subpixels: light-emitting elements 110a, 110b, and 110c. For example, the light-emitting element 110a may be a blue light-emitting element, the light-emitting element 110b may be a red light-emitting element, and the light-emitting element 110c may be a green light-emitting element.

The pixel 150 illustrated in FIG. 10B includes the light-emitting element 110a having a substantially trapezoidal top surface shape with rounded corners, the light-emitting element 110b having a substantially triangle top surface shape with rounded corners, and the light-emitting element 110c having a substantially tetragonal or substantially hexagonal top surface shape with rounded corners. In addition, the light-emitting element 110a has a larger light-emitting area than the light-emitting element 110b. In this manner, the shapes and sizes of the light-emitting elements can be determined independently. For example, the size of a light-emitting element with higher reliability can be made smaller. For example, the light-emitting element 110a may be a green light-emitting element, the light-emitting element 110b may be a red light-emitting element, and the light-emitting element 110c may be a blue light-emitting element.

Pixels 124a and 124b illustrated in FIG. 10C employ PenTile arrangement. FIG. 10C illustrates an example in which the pixels 124a each including the light-emitting element 110a and the light-emitting element 110b and the pixels 124b each including the light-emitting element 110b and the light-emitting element 110c are alternately arranged. For example, the light-emitting element 110a may be a red light-emitting element, the light-emitting element 110b may be a green light-emitting element, and the light-emitting element 110c may be a blue light-emitting element.

The pixels 124a and 124b illustrated in FIG. 10D and FIG. 10E employ delta arrangement. The pixel 124a includes two light-emitting elements (the light-emitting elements 110a and 110b) in an upper row (a first row) and one light-emitting element (the light-emitting element 110c) in a lower row (a second row). The pixel 124b includes one light-emitting element (the light-emitting element 110c) in the upper row (the first row) and two light-emitting elements (the light-emitting elements 110a and 110b) in the lower row (the second row). For example, the light-emitting element 110a may be a red light-emitting element, the light-emitting element 110b may be a green light-emitting element, and the light-emitting element 110c may be a blue light-emitting element.

FIG. 10D illustrates an example in which each light-emitting element has a substantially tetragonal top surface shape with rounded corners, and FIG. 10E illustrates an example in which each light-emitting element has a circular top surface shape.

FIG. 10F illustrates an example in which light-emitting elements of different colors are arranged in a zigzag manner. Specifically, the positions of top sides of two light-emitting elements arranged in a column direction (e.g., the light-emitting element 110a and the light-emitting element 110b or the light-emitting element 110b and the light-emitting element 110c) are not aligned in a top view. For example, the light-emitting element 110a may be a red light-emitting element, the light-emitting element 110b may be a green light-emitting element, and the light-emitting element 110c may be a blue light-emitting element.

In a photolithography method, as a pattern to be processed becomes finer, the influence of light diffraction becomes more difficult to ignore: accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a light-emitting element has a polygonal shape with rounded corners, an elliptical shape, a circular shape, or the like in some cases.

Furthermore, in a method for manufacturing a display panel in one embodiment of the present invention, the EL layer is processed into an island shape with use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of a resist material. An insufficiently cured resist film might have a shape different from a desired shape at the time of processing. As a result, a top surface of the EL layer has a polygonal shape with rounded corners, an elliptical shape, a circular shape, or the like in some cases. For example, when a resist mask with a square top surface is intended to be formed, a resist mask with a circular top surface might be formed, and the top surface of the EL layer might be circular.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

The above is the description of the pixel layout.

At least part of this embodiment can be implemented in appropriate combination with the other embodiments described in this specification.

### Embodiment 3

In this embodiment, other structure examples of a display device (display panel) that can be used for the electronic device of one embodiment of the present invention will be described. Display devices (display panels) described below as examples can be used as the display device 11a, the display device 11b, and the like in Embodiment 1.

The display device of this embodiment can be a high-resolution display device. For example, display devices of one embodiment of the present invention can be used for display portions of information terminal devices (wearable devices) such as wristwatch-type and bracelet-type information terminal devices and display portions of wearable devices that can be worn on a head, such as VR devices like head-mounted displays and glasses-type AR devices.

### [Display Module]

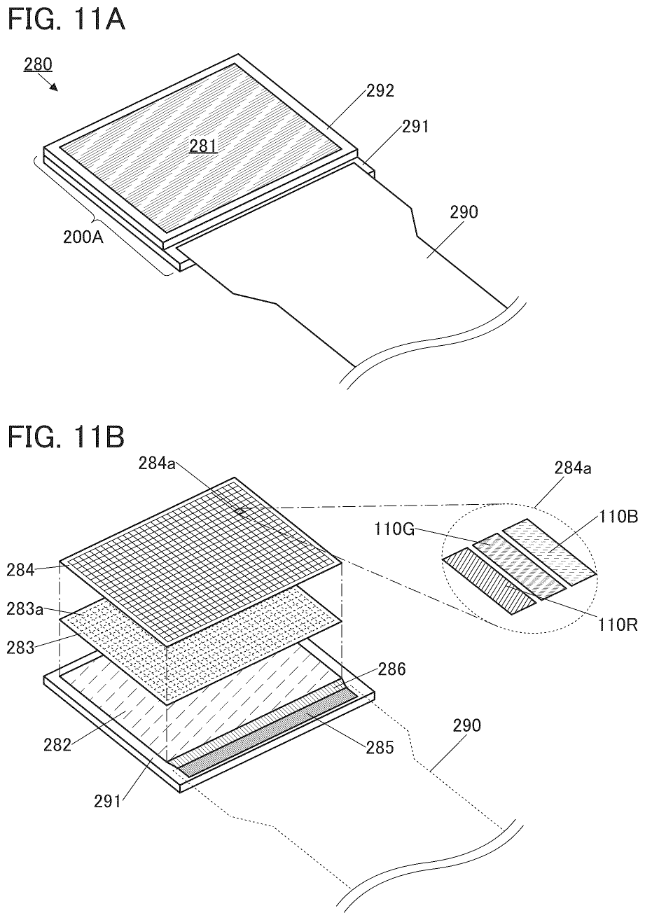

FIG. 11A is a perspective view of a display module 280. The display module 280 includes a display device 200A and an FPC 290. Note that a display panel included in the display module 280 is not limited to the display device 200A and may be any of a display device 200B to a display device 200F described later.

The display module 280 includes a substrate 291 and a substrate 292. The display module 280 includes a display portion 281. The display portion 281 is a region where an image is displayed.

FIG. 11B shows a perspective view schematically illustrating a structure on the substrate 291 side. Over the substrate 291, a circuit portion 282, a pixel circuit portion 283 over the circuit portion 282, and a pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is shown on the right side of FIG. 11B. The pixel 284a includes the light-emitting element 110R that emits red light, the light-emitting element 110G that emits green light, and the light-emitting element 110B that emits blue light.

The pixel circuit portion 283 includes a plurality of pixel circuits 283a arranged periodically. One pixel circuit 283a is a circuit controlling light emission of three light-emitting devices included in one pixel 284a. One pixel circuit 283a may be provided with three circuits for controlling light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display panel is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included. In addition, a transistor provided in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, and the like to the circuit portion 282 from the outside. An IC may be mounted on the FPC 290.

The display module 280 can have a structure where one or both of the pixel circuit portion 283 and the circuit portion 282 are stacked below the pixel portion 284: hence, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as a head-mounted display or a glasses-type AR device. For example, even with a structure where the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be suitably used for a display portion of a wearable electronic device, such as a wrist watch.

### [Display Device 200A]

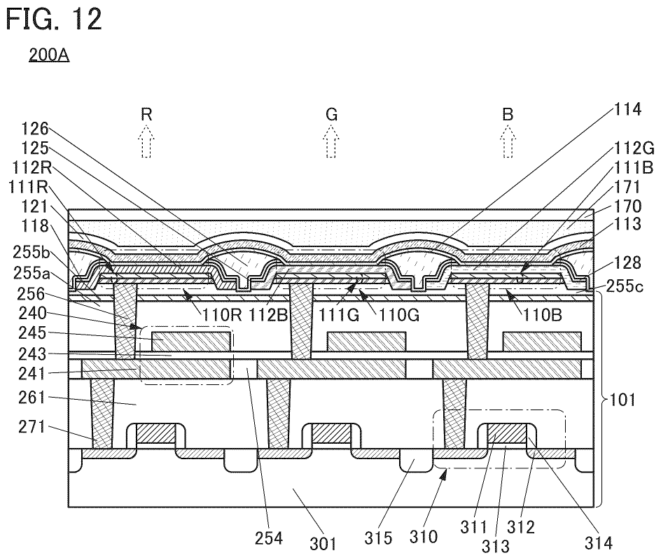

The display device 200A illustrated in FIG. 12A includes a substrate 301, the light-emitting elements 110R, 110G, and 110B, a capacitor 240, and a transistor 310.

The substrate 301 corresponds to the substrate 291 in FIG. 11A and FIG. 11B.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region of the substrate 301 which is doped with an impurity, and functions as one of a source and a drain. The insulating layers 314 are provided to cover side surfaces of the conductive layer 311.

In addition, an element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned between these conductive layers. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b.

An inorganic insulating film can be suitably used for each of the insulating layer 255a, the insulating layer 255b, and the insulating layer 255c. For example, it is preferable that a silicon oxide film be used for each of the insulating layer 255a and the insulating layer 255c and that a silicon nitride film be used for the insulating layer 255b. This enables the insulating layer 255b to function as an etching protective film. Although this embodiment shows an example in which the insulating layer 255c is partly etched and a depressed portion is formed, the depressed portion is not necessarily provided in the insulating layer 255c.

The light-emitting element 110R, the light-emitting element 110G, and the light-emitting element 110B are provided over the insulating layer 255c. Embodiment 1 can be referred to for the structures of the light-emitting element 110R, the light-emitting element 110G, and the light-emitting element 110B.

In the display device 200A, since the light-emitting devices of different colors are separately formed, a change in chromaticity between light emission at low luminance and light emission at high luminance is small. Furthermore, since the organic layers 112R, 112G, and 112B are separated from each other, crosstalk generated between adjacent subpixels can be inhibited while the display panel has high definition. Accordingly, the display panel can have high resolution and high display quality.

In a region between adjacent light-emitting elements, the insulating layer 125, the resin layer 126, and the layer 128 are provided.

The pixel electrode 111R, the pixel electrode 111G, and the pixel electrode 111B of the light-emitting elements are each electrically connected to one of the source and the drain of the transistor 310 through a plug 256 that is embedded in the insulating layer 255a, the insulating layer 255b, and the insulating layer 255c, the conductive layer 241 that is embedded in the insulating layer 254, and the plug 271 that is embedded in the insulating layer 261. The top surface of the insulating layer 255c and the top surface of the plug 256 are level or substantially level with each other. A variety of conductive materials can be used for the plugs.

In addition, the protective layer 121 is provided over the light-emitting elements 110R, 110G, and 110B. A substrate 170 is attached to the protective layer 121 with an adhesive layer 171.

An insulating layer covering an end portion of a top surface of the pixel electrode 111 is not provided between two adjacent pixel electrodes 111. Thus, the distance between adjacent light-emitting elements can be extremely narrowed. Accordingly, the display device can have high resolution or high definition.

### [Display Device 200B]

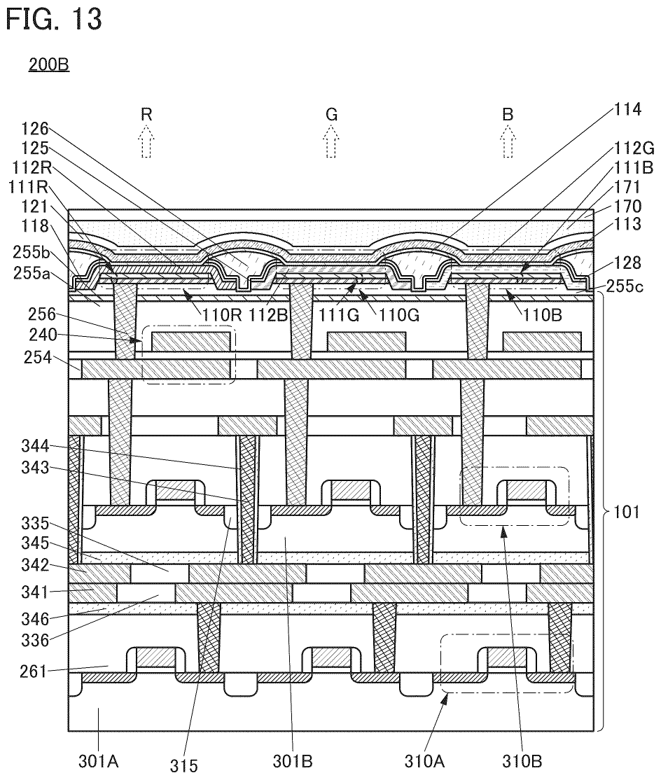

The display device 200B illustrated in FIG. 13 has a structure in which a transistor 310A and a transistor 310B in each of which a channel is formed in a semiconductor substrate are stacked. Note that in the following description of the display panel, the description of portions similar to those of the above display panel is omitted in some cases.

The display device 200B has a structure where a substrate 301B provided with the transistors 310B, the capacitors 240, and the light-emitting devices is attached to a substrate 301A provided with the transistors 310A.

Here, an insulating layer 345 is provided on the bottom surface of the substrate 301B, and an insulating layer 346 is provided over the insulating layer 261 provided over the substrate 301A. The insulating layers 345 and 346 are insulating layers functioning as protective layers and can inhibit diffusion of impurities into the substrate 301B and the substrate 301A. As the insulating layers 345 and 346, an inorganic insulating film that can be used as the protective layer 121 or an insulating layer 332 can be used.

The substrate 301B is provided with a plug 343 that penetrates the substrate 301B and the insulating layer 345. Here, an insulating layer 344 functioning as a protective layer is preferably provided to cover the side surface of the plug 343.

A conductive layer 342 is provided under the insulating layer 345 on the substrate 301B. The conductive layer 342 is embedded in an insulating layer 335, and the bottom surfaces of the conductive layer 342 and the insulating layer 335 are planarized. The conductive layer 342 is electrically connected to the plug 343.

A conductive layer 341 is provided over the insulating layer 346 over the substrate 301A. The conductive layer 341 is embedded in an insulating layer 336, and the top surfaces of the conductive layer 341 and the insulating layer 336 are planarized.

The conductive layer 341 and the conductive layer 342 are preferably formed using the same conductive material. For example, it is possible to use a metal film containing an element selected from A1, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ Cu—Cu (copper-to-copper) direct bonding (a technique for achieving electrical continuity by connecting Cu (copper) pads).

### [Display Device 200C]

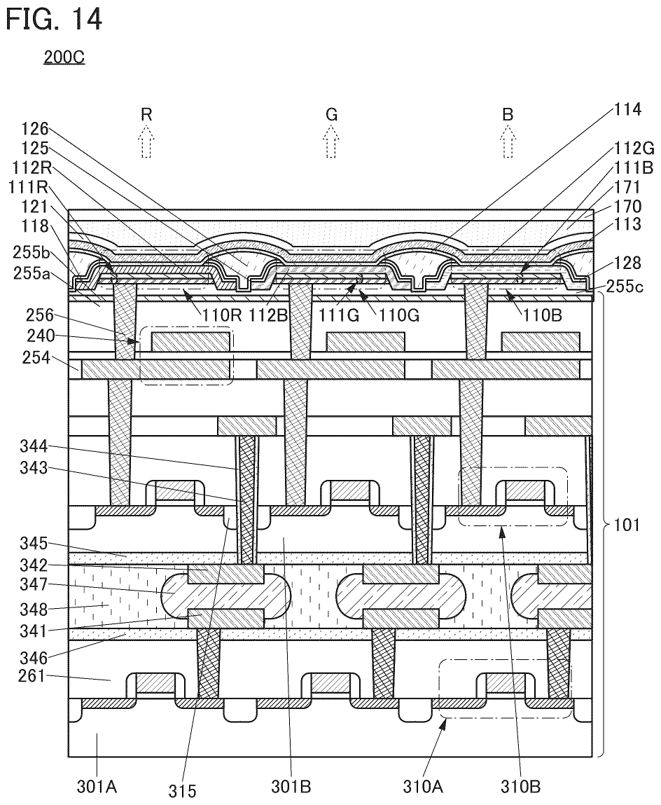

The display device 200C illustrated in FIG. 14 has a structure where the conductive layer 341 and the conductive layer 342 are bonded to each other through a bump 347.

As shown in FIG. 14, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Device 200D]

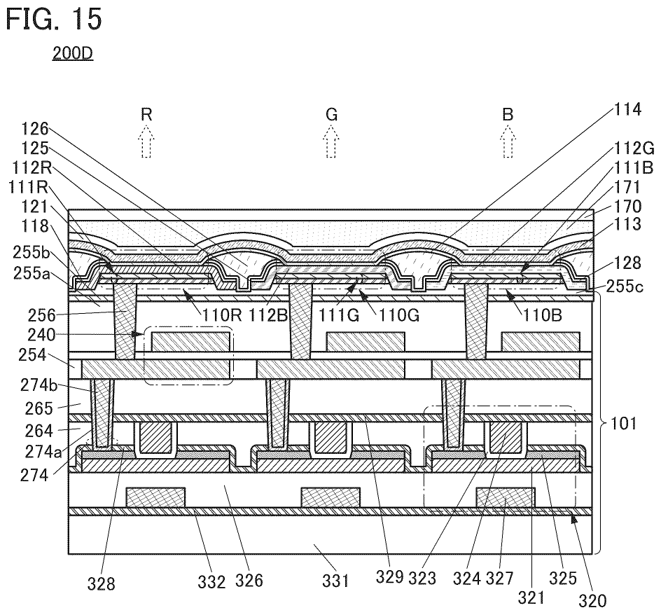

The display device 200D illustrated in FIG. 15 differs from the display device 200A mainly in a transistor structure.

A transistor 320 is a transistor (OS transistor) that includes a metal oxide (also referred to as an oxide semiconductor) in its semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 11A and FIG. 11B.

The insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film exhibiting semiconductor characteristics. The pair of conductive layers 325 is provided over and in contact with the semiconductor layer 321 and functions as a source electrode and a drain electrode.

An insulating layer 328 is provided to cover the top surfaces and the side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The conductive layer 324 and the insulating layer 323 that is in contact with the top surface of the semiconductor layer 321 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so as to be level or substantially level with each other, and an insulating layer 329 and an insulating layer 265 are provided to cover these lavers.

The insulating layer 264 and the insulating layer 265 function as interlayer insulating layers. The insulating layer 329 functions as a barrier layer that prevents diffusion of impurities such as water or hydrogen from the insulating layer 265 or the like into the transistor 320. For the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a covering the side surface of an opening formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material that does not easily allow diffusion of hydrogen and oxygen is preferably used.

Note that there is no particular limitation on the structure of the transistors included in the display device of this embodiment. For example, a planar transistor, a staggered transistor, an inverted staggered transistor, or the like can be used. In addition, either of a top-gate transistor structure and a bottom-gate transistor structure may be employed. Alternatively, gates may be provided above and below a semiconductor layer where a channel is formed.

The structure in which the semiconductor layer where a channel is formed is provided between two gates is used for the transistor 320. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the semiconductor layer of the transistor, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity because degradation of transistor characteristics can be inhibited.

The band gap of a metal oxide used for the semiconductor layer of the transistor is preferably greater than or equal to 2 eV, further preferably greater than or equal to 2.5 eV. With use of a metal oxide having a wide bandgap, the off-state current of the OS transistor can be reduced.

A metal oxide preferably contains at least indium or zinc, and further preferably contains indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

Alternatively, the semiconductor layer of the transistor may contain silicon. Examples of silicon include amorphous silicon and crystalline silicon (low-temperature polysilicon, single crystal silicon, or the like).

Examples of the metal oxide that can be used for the semiconductor layer include indium oxide, gallium oxide, and zinc oxide. The metal oxide preferably includes two or three kinds selected from indium, an element M, and zinc. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. Specifically, the element M is preferably one or more kinds selected from aluminum, gallium, yttrium, and tin.

It is particularly preferable that an oxide containing indium, gallium, and zinc (also referred to as IGZO) be used as the metal oxide used for the semiconductor layer. Alternatively, it is preferable to use an oxide containing indium, tin, and zinc (also referred to as ITZO (registered trademark)). Further alternatively, it is preferable to use an oxide containing indium, gallium, tin, and zinc. Alternatively, it is preferable to use an oxide containing indium, aluminum, and zinc (also referred to as IAZO). Further alternatively, it is preferable to use an oxide containing indium, aluminum, gallium, and zinc (also referred to as IAGZO).

When the metal oxide used for the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, in the case where the atomic ratio is described as In:Ga:Zn=4:2:3 or a composition in the neighborhood thereof, a case is included where Ga is greater than or equal to 1 and less than or equal to 3 and Zn is greater than or equal to 2 and less than or equal to 4 with In being 4. In addition, in the case where the atomic ratio is described as In:Ga:Zn=5:1:6 or a composition in the neighborhood thereof, a case is included where Ga is greater than 0.1 and less than or equal to 2 and Zn is greater than or equal to 5 and less than or equal to 7 with In being 5. In addition, in the case where the atomic ratio is described as In:Ga:Zn=1:1:1 or a composition in the neighborhood thereof, a case is included where Ga is greater than 0.1 and less than or equal to 2 and Zn is greater than 0.1 and less than or equal to 2 with In being 1.

The semiconductor layer may include two or more metal oxide layers having different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be favorably employed. Gallium or aluminum is particularly preferably used as the element M.

Alternatively, a stacked structure of one selected from indium oxide, indium gallium oxide, and IGZO, and one selected from IAZO, IAGZO, and ITZO (registered trademark) may be employed, for example.

As the oxide semiconductor having crystallinity, a CAAC (c-axis aligned crystalline)-OS, an nc (nanocrystalline)-OS, and the like are given.

An OS transistor has much higher field-effect mobility than a transistor using amorphous silicon. In addition, an OS transistor has an extremely low leakage current between a source and a drain in an off state (also referred to as off-state current), and charge accumulated in a capacitor that is connected in series to the transistor can be retained for a long period. Furthermore, the power consumption of the display device can be reduced with the OS transistor.

To increase the emission luminance of the light-emitting device included in a pixel circuit, it is necessary to increase the amount of current flowing through the light-emitting device. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Thus, with use of an OS transistor as a driving transistor included in the pixel circuit, the amount of current flowing through the light-emitting device can be increased, resulting in an increase in emission luminance of the light-emitting device.

When transistors operate in a saturation region, a change in source-drain current relative to a change in gate-source voltage is smaller in an OS transistor than in a Si transistor. Accordingly, when an OS transistor is used as the driving transistor included in the pixel circuit, current flowing between the source and the drain can be set minutely by a change in gate-source voltage: hence, the amount of current flowing through the light-emitting device can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made flow through an OS transistor than through a Si transistor. Thus, with use of an OS transistor as a driving transistor, current can be made flow stably through the light-emitting device, for example, even when a variation in current-voltage characteristics of the EL device occurs. In other words, when the OS transistor operates in the saturation region, the source-drain current hardly changes with an increase in the source-drain voltage: hence, the emission luminance of the light-emitting device can be stable.

As described above, with use of an OS transistor as the driving transistor included in the pixel circuit, it is possible to achieve “inhibition of black floating”, “increase in emission luminance”, “increase in the number of gray levels”, “inhibition of variation in light-emitting devices”, and the like.

### [Display Device 200E]

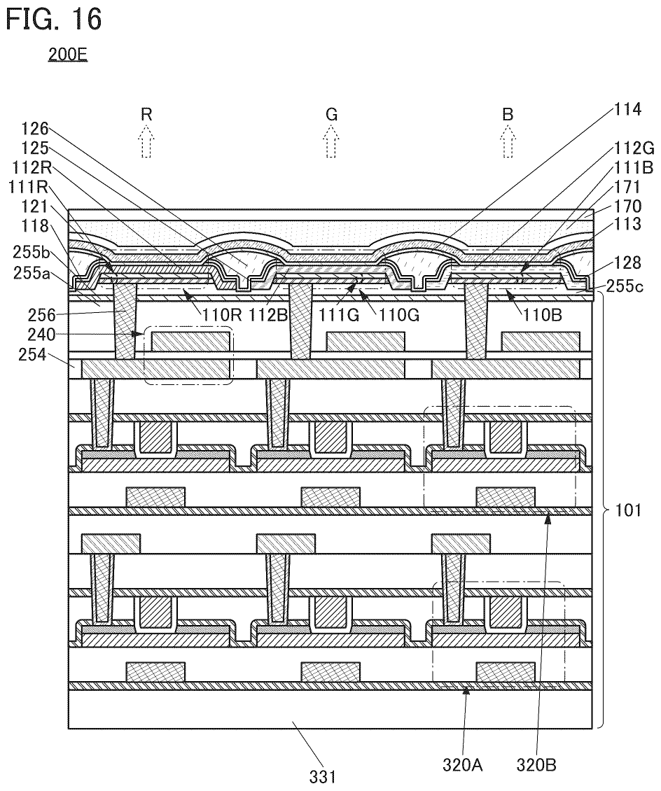

The display device 200E illustrated in FIG. 16 has a structure in which a transistor 320A and a transistor 320B each including an oxide semiconductor in a semiconductor where a channel is formed are stacked.

The display device 200D can be referred to for the structure of the transistor 320A, the transistor 320B, and other peripheral structures.

Note that although the structure where two transistors including an oxide semiconductor are stacked is described here, the present invention is not limited thereto. For example, three or more transistors may be stacked.

### [Display Device 200F]

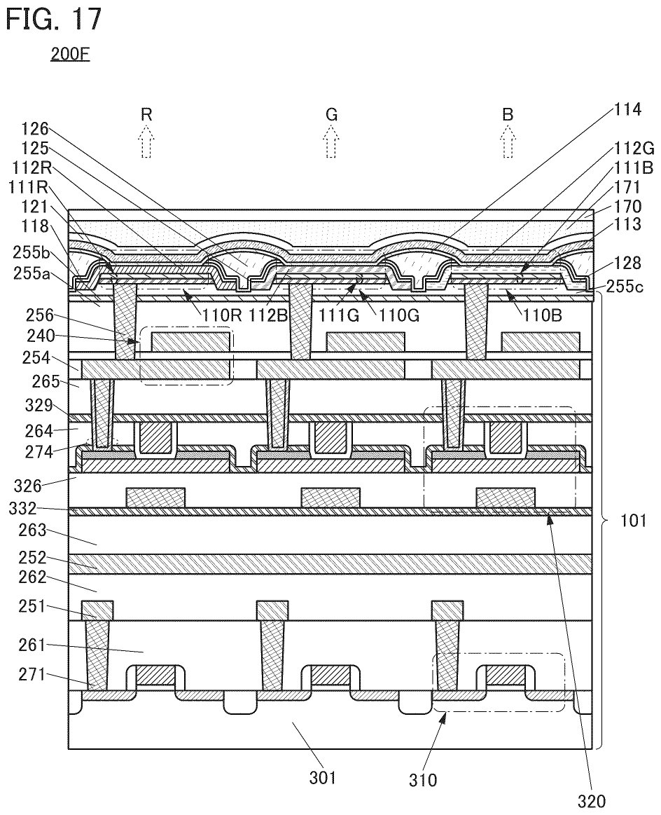

The display device 200F illustrated in FIG. 17 has a structure in which the transistor 310 whose channel is formed in the substrate 301 and the transistor 320 including a metal oxide in the semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices: thus, the display panel can be downsized as compared with the case where a driver circuit is provided around a display region.

### [Display Device 200G]

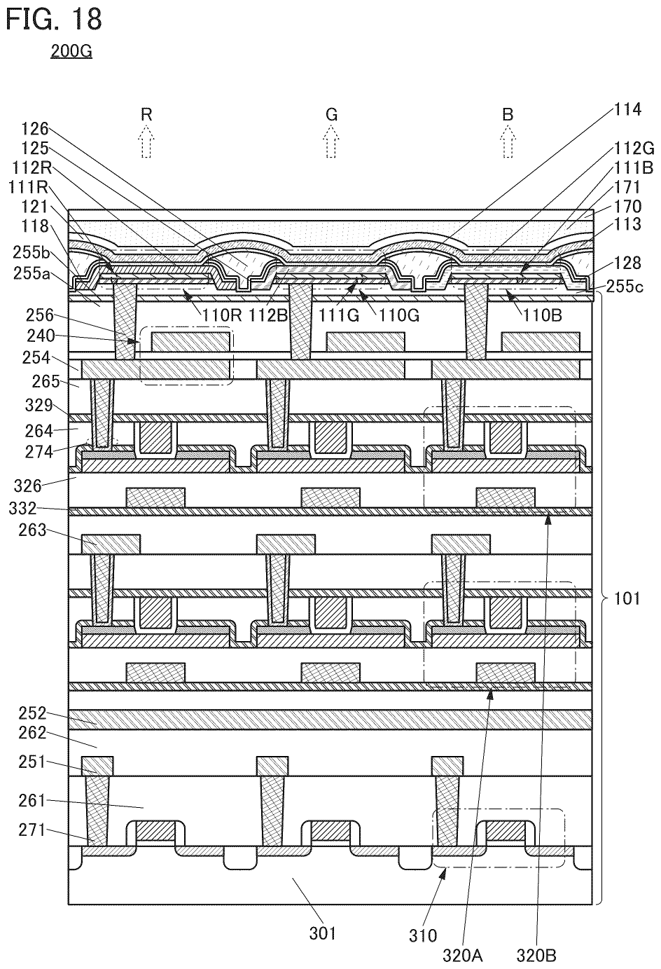

The display device 200G illustrated in FIG. 18 has a structure in which the transistor 310 whose channel is formed in the substrate 301 and the transistor 320A and the transistor 320B each including a metal oxide in the semiconductor layer where a channel is formed are stacked.

The transistor 320A can be used as a transistor included in a pixel circuit. The transistor 310 can be used as a transistor included in the pixel circuit or a transistor included in a driver circuit (a gate line driver circuit or a source line driver circuit) for driving the pixel circuit. The transistor 320B may be used as a transistor included in a pixel circuit or the transistor included in the driver circuit. The transistor 310, the transistor 320A, and the transistor 320B can also be used as transistors included in a variety of circuits such as an arithmetic circuit and a memory circuit.

At least part of this embodiment can be implemented in appropriate combination with the other embodiments described in this specification.

### Embodiment 4

In this embodiment, a light-emitting device (light-emitting element) that can be used in the display device according to one embodiment of the present invention will be described.

In this specification and the like, a device fabricated using a metal mask or an FMM (a fine metal mask, a high-resolution metal mask) may be referred to as a device having an MM (a metal mask) structure. In this specification and the like, a device fabricated without using a metal mask or an FMM may be referred to as a device having an MML (a metal maskless) structure.

In this specification and the like, a structure where at least light-emitting layers of light-emitting devices having different emission wavelengths are separately formed is sometimes referred to as an SBS (Side By Side) structure. The SBS structure allows optimization of materials and structures of light-emitting devices and thus can extend freedom of choice of the materials and the structures, which makes it easy to improve the luminance and the reliability.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Examples of the layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

As the light-emitting device, an OLED (Organic Light Emitting Diode) or a QLED (Quantum-dot Light Emitting Diode) is preferably used. Examples of a light-emitting substance included in the light-emitting device include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material). In addition, an LED (Light Emitting Diode) such as a micro LED can also be used as the light-emitting device.

The light-emitting device can emit infrared, red, green, blue, cyan, magenta, yellow, or white light, for example. Furthermore, the color purity can be further increased when the light-emitting device has a microcavity structure.

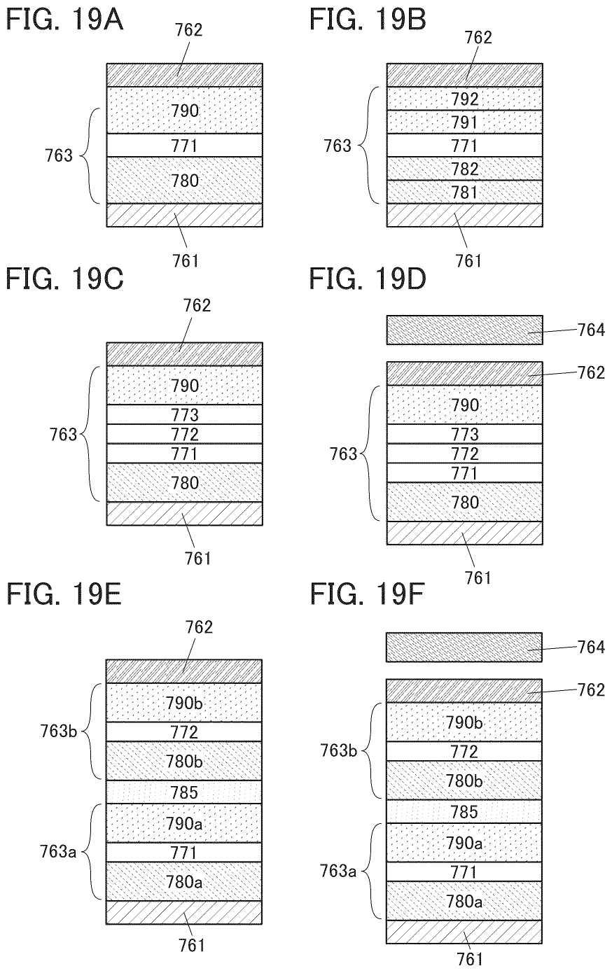

As illustrated in FIG. 19A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790. The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the above structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 19A is referred to as a single structure in this specification.

FIG. 19B is a variation example of the EL layer 763 included in the light-emitting device illustrated in FIG. 19A. Specifically, the light-emitting device shown in FIG. 19B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected into the light-emitting layer 771, and the efficiency of the recombination of carriers in the light-emitting layer 771 can be increased.

Note that structures in which a plurality of light-emitting layers (the light-emitting layer 771, a light-emitting layer 772, and a light-emitting layer 773) are provided between the layer 780 and the layer 790 as illustrated in FIG. 19C and FIG. 19D are other variations of the single structure. Although FIG. 19C and FIG. 19D illustrate the examples where three light-emitting layers are included, the light-emitting layer in the light-emitting device with a single structure may include two or four or more light-emitting layers. A light-emitting device having a single structure may include a buffer layer between two light-emitting layers.

A structure where a plurality of light-emitting units (a light-emitting unit 763a and a light-emitting unit 763b) are connected in series with a charge-generation layer 785 (also referred to as an intermediate layer) therebetween as illustrated in FIG. 19E and FIG. 19F is referred to as a tandem structure in this specification. Note that the tandem structure may be referred to as a stack structure. The tandem structure enables a light-emitting device capable of high-luminance light emission. Furthermore, the tandem structure reduces the amount of current needed for obtaining the same luminance as compared with the single structure, and thus can improve the reliability.

Note that FIG. 19D and FIG. 19F illustrate examples where the display device includes a layer 764 overlapping with the light-emitting device. FIG. 19D illustrates an example where the layer 764 overlaps with the light-emitting device illustrated in FIG. 19C, and FIG. 19F illustrates an example where the layer 764 overlaps with the light-emitting device illustrated in FIG. 19E.

One or both of a color conversion layer and a color filter (a coloring layer) can be used as the layer 764.

In FIG. 19C and FIG. 19D, light-emitting substances that emit light of the same color, or moreover, the same light-emitting substance may be used for the light-emitting layer 771, the light-emitting layer 772, and the light-emitting layer 773. For example, a light-emitting substance emitting blue light may be used for the light-emitting layer 771, the light-emitting layer 772, and the light-emitting layer 773. In a subpixel that emits blue light, blue light emitted from the light-emitting device can be extracted. In a subpixel that emits red light and a subpixel that emits green light, by providing a color conversion layer as the layer 764 illustrated in FIG. 19D, blue light emitted from the light-emitting device can be converted into light with a longer wavelength, and red light or green light can be extracted.

Alternatively, light-emitting substances that emit light of different colors may be used for the light-emitting layer 771, the light-emitting layer 772, and the light-emitting layer 773. White light emission can be obtained when the light-emitting layer 771, the light-emitting layer 772, and the light-emitting layer 773 emit light of complementary colors. The light-emitting device having a single structure preferably includes a light-emitting layer including a light-emitting substance emitting blue light and a light-emitting layer including a light-emitting substance emitting visible light with a longer wavelength than blue light, for example.

In the case where the light-emitting device having a single structure includes three light-emitting layers, for example, a light-emitting layer including a light-emitting substance emitting red (R) light, a light-emitting layer including a light-emitting substance emitting green (G) light, and a light-emitting layer including a light-emitting substance emitting blue (B) light are preferably included. The stacking order of the light-emitting layers can be R, G, and B from the anode side or R. B, and G from the anode side, for example. In that case, a buffer layer may be provided between R and G or between R and B.

In the case where the light-emitting device having a single structure includes two light-emitting layers, for example, a light-emitting layer containing a light-emitting substance emitting blue (B) light and a light-emitting layer containing a light-emitting substance emitting yellow light are preferably included. Such a structure may be referred to as a BY single structure.

A color filter may be provided as the layer 764 illustrated in FIG. 19D. When white light passes through a color filter, light of a desired color can be obtained.

The light-emitting device emitting white light preferably contains two or more kinds of light-emitting substances. To obtain white light emission, two or more kinds of light-emitting substances are selected such that they emit light of complementary colors. For example, when an emission color of a first light-emitting layer and an emission color of a second light-emitting layer are complementary colors, the light-emitting device can be configured to emit white light as a whole. The same applies to a light-emitting device including three or more light-emitting layers.

In FIG. 19E and FIG. 19F, light-emitting substances that emit light of the same color, or moreover, the same light-emitting substance may be used for the light-emitting layer 771 and the light-emitting layer 772.

For example, in light-emitting devices included in subpixels emitting light of different colors, a light-emitting substance that emits blue light may be used for each of the light-emitting layer 771 and the light-emitting layer 772. In a subpixel that emits blue light, blue light emitted from the light-emitting device can be extracted. In the subpixel that emits red light and the subpixel that emits green light, by providing a color conversion layer as the layer 764 illustrated in FIG. 19F, blue light emitted from the light-emitting device can be converted into light with a longer wavelength, and red light or green light can be extracted.

In the case where light-emitting devices with the structure illustrated in FIG. 19E or FIG. 19F are used in subpixels emitting light of different colors, light-emitting substances may be different between the subpixels. Specifically, in the light-emitting device included in the subpixel emitting red light, a light-emitting substance that emits red light may be used for each of the light-emitting layer 771 and the light-emitting layer 772. Similarly, in the light-emitting device included in the subpixel emitting green light, a light-emitting substance that emits green light may be used for each of the light-emitting layer 771 and the light-emitting layer 772. In the light-emitting device included in the subpixel emitting blue light, a light-emitting substance that emits blue light may be used for each of the light-emitting layer 771 and the light-emitting layer 772. A display device with such a structure includes a light-emitting device with a tandem structure and can be regarded to have an SBS structure. Thus, the display device can take advantages of both the tandem structure and the SBS structure. Accordingly, a highly reliable light-emitting device capable of high-luminance light emission can be obtained.

In FIG. 19E and FIG. 19F, light-emitting substances of different emission colors may be used for the light-emitting layer 771 and the light-emitting layer 772. White light emission can be obtained when the light-emitting layer 771 and the light-emitting layer 772 emit light of complementary colors. A color filter may be provided as the layer 764 illustrated in FIG. 19F. When white light passes through a color filter, light of a desired color can be obtained.

Although FIG. 19E and FIG. 19F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

In addition, although FIG. 19E and FIG. 19F illustrate the light-emitting device including two light-emitting units, one embodiment of the present invention is not limited thereto. The light-emitting device may include three or more light-emitting units.

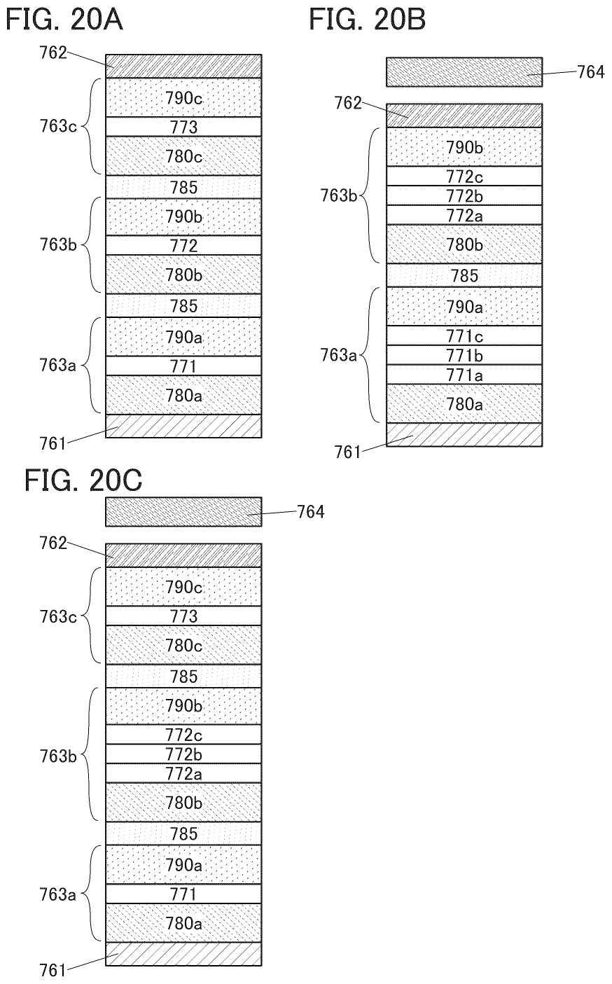

Specifically, the light-emitting device may have any of structures illustrated in FIG. 20A to FIG. 20C.

FIG. 20A illustrates a structure including three light-emitting units. Note that a structure including two light-emitting units and a structure including three light-emitting units may be referred to as a two-unit tandem structure and a three-unit tandem structure, respectively.

In addition, in the structure illustrated in FIG. 20A, a plurality of light-emitting units (the light-emitting unit 763a, the light-emitting unit 763b, and a light-emitting unit 763c) are connected in series with the charge-generation layers 785 therebetween. The light-emitting unit 763a includes a layer 780a, the light-emitting layer 771, and a layer 790a. The light-emitting unit 763b includes a layer 780b, the light-emitting layer 772, and a layer 790b. The light-emitting unit 763c includes a layer 780c, the light-emitting layer 773, and a layer 790c.

In the structure illustrated in FIG. 20A, the light-emitting layer 771, the light-emitting layer 772, and the light-emitting layer 773 preferably contain light-emitting substances that emit light of the same color. Specifically, the light-emitting layer 771, the light-emitting layer 772, and the light-emitting layer 773 can each contain a red (R) light-emitting substance (a so-called three-unit tandem structure of R\R\R): the light-emitting layer 771, the light-emitting layer 772, and the light-emitting layer 773 can each contain a green (G) light-emitting substance (a so-called three-unit tandem structure of G\G\G): or the light-emitting layer 771, the light-emitting layer 772, and the light-emitting layer 773 can each contain a blue (B) light-emitting substance (a so-called three-unit tandem structure of B\B\B).

Note that the structure containing the light-emitting substances that emit light of the same color is not limited to the above structure. For example, a light-emitting device with a tandem structure may be employed in which light-emitting units each including a plurality of light-emitting substances are stacked as illustrated in FIG. 20B. FIG. 20B illustrates a structure in which a plurality of light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In the structure illustrated in FIG. 20B, light-emitting substances for the light-emitting layer 771a, the light-emitting layer 771b, and the light-emitting layer 771c are selected so as to emit light of complementary colors for white (W) light emission. Furthermore, light-emitting substances for the light-emitting layer 772a, the light-emitting layer 772b, and the light-emitting layer 772c are selected so as to emit light of complementary colors for white (W) light emission. That is, the structure illustrated in FIG. 20C is a two-unit tandem structure of WWW. Note that there is no particular limitation on the stacking order of the light-emitting substances emitting light of complementary colors for the light-emitting layer 771a, the light-emitting layer 771b, and the light-emitting layer 771c. The practitioner can select the optimal stacking order as appropriate. Although not illustrated, a three-unit tandem structure of W\W\W or a tandem structure with four or more units may be employed.

In the case of a light-emitting device with a tandem structure, any of the following structure may be employed, for example: a two-unit tandem structure of BY including a light-emitting unit that emits yellow (Y) light and a light-emitting unit that emits blue (B) light: a two-unit tandem structure of R·G\B including a light-emitting unit that emits red (R) and green (G) light and a light-emitting unit that emits blue (B) light: a three-unit tandem structure of B\Y\B including a light-emitting unit that emits blue (B) light, a light-emitting unit that emits yellow (Y) light, and a light-emitting unit that emits blue (B) light in this order: a three-unit tandem structure of B\YG\B including a light-emitting unit that emits blue (B) light, a light-emitting unit that emits yellow-green (YG) light, and a light-emitting unit that emits blue (B) light in this order; and a three-unit tandem structure of B\G\B including a light-emitting unit that emits blue (B) light, a light-emitting unit that emits green (G) light, and a light-emitting unit that emits blue (B) light in this order.

As illustrated in FIG. 20C, a light-emitting unit including one light-emitting substance and a light-emitting unit including a plurality of light-emitting substances may be used in combination.

Specifically, in the structure illustrated in FIG. 20C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 20C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y: a two-unit structure of B and a light-emitting unit X: a three-unit structure of B, Y, and B; and a three-unit structure of B, X, and B. Examples of the number of light-emitting layers stacked in the light-emitting unit X and the order of colors from the anode side include a two-layer structure of R and Y: a two-layer structure of R and G: a two-layer structure of G and R: a three-layer structure of G, R, and G; and a three-layer structure of R, G, and R. Another layer may be provided between two light-emitting layers.

Also in FIG. 19C and FIG. 19D, the layer 780 and the layer 790 may each independently have a stacked-layer structure of two or more layers as illustrated in FIG. 19B.

In FIG. 19E and FIG. 19F, the light-emitting unit 763a includes the layer 780a, the light-emitting layer 771, and the layer 790a, and the light-emitting unit 763b includes the layer 780b, the light-emitting layer 772, and the layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the above structures of the layer 780a and the layer 790a are replaced with each other, and the above structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating the light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

Next, materials that can be used for the light-emitting device will be described.

A conductive film that transmits visible light is used for the electrode through which light is extracted, which is either the lower electrode 761 or the upper electrode 762. A conductive film that reflects visible light is preferably used as the electrode through which light is not extracted. In the case where a display device includes a light-emitting device emitting infrared light, a conductive film transmitting visible light and infrared light is preferably used as the electrode through which light is extracted, and a conductive film reflecting visible light and infrared light is preferably used as the electrode through which light is not extracted.

A conductive film that transmits visible light may be used also for the electrode through which light is not extracted. In that case, the electrode is preferably placed between a reflective layer and the EL layer 763. That is, light emitted from the EL layer 763 may be reflected by the reflective layer to be extracted from the display device.

As a material that forms the pair of electrodes of the light-emitting device, a metal, an alloy, an electrically conductive compound, a mixture thereof, and the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (In—Sn oxide, also referred to as ITO), In—Si—Sn oxide (also referred to as ITSO), indium zinc oxide (In—Zn oxide), and In—W—Zn oxide. Other examples of the material include an alloy containing aluminum (aluminum alloy) such as an alloy of aluminum, nickel, and lanthanum (Al—Ni—La), and an alloy of silver, palladium, and copper (Ag—Pd—Cu, also referred to as APC). Other examples of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting devices preferably employ a microcavity structure. Therefore, one of the pair of electrodes of the light-emitting device is preferably an electrode having properties of transmitting and reflecting visible light (transflective electrode), and the other is preferably an electrode having a property of reflecting visible light (reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer that can be used as an electrode having a visible-light-transmitting property (also referred to as a transparent electrode).

The light transmittance of the transparent electrode is higher than or equal to 40%. For example, an electrode having a visible light (light with wavelengths greater than or equal to 400 nm and less than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity less than or equal to 1×10⁻² Ωcm.

The light-emitting device includes at least the light-emitting layer. In addition to the light-emitting layer, the light-emitting device may further include a layer including any of a substance having a high hole-injection property, a substance having a high hole-transport property, a hole-blocking material, a substance having a high electron-transport property, an electron-blocking material, a substance having a high electron-injection property, a substance having a bipolar property (a substance with a high electron- and hole-transport property), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer contains one or more kinds of light-emitting substances. As the light-emitting substance, a substance whose emission color is blue, violet, bluish violet, green, yellow-green, yellow, orange, red, or the like is appropriately used. As the light-emitting substance, a substance emitting near-infrared light can also be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton: an organometallic complex (particularly an iridium complex) having a phenylpyridine derivative including an electron-withdrawing group as a ligand: a platinum complex; and a rare earth metal complex.

The light-emitting layer may contain one or more kinds of organic compounds (e.g., a host material or an assist material) in addition to the light-emitting substance (guest material). As one or more kinds of organic compounds, one or both of a substance having a high hole-transport property (a hole-transport material) and a substance having a high electron-transport property (an electron-transport material) can be used. As the hole-transport material, it is possible to use a material having a high hole-transport property which can be used for the hole-transport layer and will be described later. As the electron-transport material, it is possible to use a material having a high electron-transport property which can be used for the electron-transport layer and will be described later. As one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With this structure, the high efficiency, low-voltage driving, and long lifetime of the light-emitting device can be achieved at the same time.

The hole-injection layer is a layer that injects holes from the anode to the hole-transport layer and contains a material with a high hole-injection property. Examples of the material with a high hole-injection property include an aromatic amine compound, and a composite material containing a hole-transport material and an acceptor material (an electron-accepting material).

As the hole-transport material, it is possible to use a material having a high hole-transport property which can be used for the hole-transport layer and will be described later.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable because it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used.

As the material with a high hole-injection property, a material containing a hole-transport material and the above-described oxide of a metal belonging to any of Group 4 to Group 8 of the periodic table (typically, molybdenum oxide) may be used, for example.

The hole-transport layer is a layer that transports holes, which are injected from the anode by the hole-injection layer, to the light-emitting layer. The hole-transport layer is a layer that contains a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, a material with a high hole-transport property, such as a π-electron rich heteroaromatic compound (e.g., a carbazole derivative, a thiophene derivative, or a furan derivative) or an aromatic amine (a compound having an aromatic amine skeleton), is preferable.

The electron-blocking layer is provided in contact with the light-emitting layer. The electron-blocking layer is a layer that has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer that transports electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a x-electron deficient heteroaromatic compound such as a nitrogen-containing heteroaromatic compound.

The hole-blocking layer is provided in contact with the light-emitting layer. The hole-blocking layer is a layer that has an electron-transport property and contains a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer that injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

The difference between the LUMO level of the material having a high electron-injection property and the work function value of the material used for the cathode is preferably small (specifically, smaller than or equal to 0.5 eV).

For the electron-injection layer, it is possible to use an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. The stacked-layer structure can be, for example, a structure where lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered: thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, and further preferably contains an inorganic compound containing lithium and oxygen (e.g., lithium oxide (Li₂O)). Alternatively, a material that can be used for the above-described electron-injection layer can be suitably used for the electron-injection buffer layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the above-described charge-generation region, electron-injection buffer layer, and electron-relay layer cannot be clearly distinguished from each other in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the above-described electron-injection layer.

When the charge-generation layer is provided between two light-emitting units to be stacked, an increase in driving voltage can be inhibited.

At least part of the structure examples, the drawings corresponding thereto, and the like described in this embodiment can be combined with the other structure examples, the other drawings, and the like as appropriate.

At least part of this embodiment can be implemented in appropriate combination with the other embodiments described in this specification.

### REFERENCE NUMERALS

10a: electronic device, 10b: electronic device, 10: electronic device, 11a: display device, 11aL: display device, 11aR: display device, 11b: display device, 11bL: display device, 11bR: display device, 11c: display device, 12L: lens, 12R: lens, 12: lens, 13a: lens, 13b: lens, 13c: lens, 13: lens, 14a: half mirror, 14b: half mirror, 14: half mirror, 15: housing, 16: half mirror, 20: eye, 21: image, 22: image, 30a: image, 30b: image, 30: image, 31a: region, 31b: region, 31c: region, 32a: region, 32c: region, 40: electronic device, 41L: camera, 41R: camera, 42: wearing tool, 100a: display device, 100b: display device, 100W: light-emitting element, 100: display device, 101: substrate, 110a: light-emitting element, 110B: light-emitting element, 110b: light-emitting element, 110c: light-emitting element, 110G: light-emitting element, 110R: light-emitting element, 110: light-emitting element, 111B: pixel electrode, 111C: connection electrode, 111G: pixel electrode, 111R: pixel electrode, 111: pixel electrode, 112B: organic layer, 112G: organic layer, 112R: organic layer, 112W: organic layer, 112: organic layer, 113: common electrode, 114: common layer, 115B: conductive layer, 115G: conductive layer, 115R: conductive layer, 115: optical adjustment layer, 116B: coloring layer, 116G: coloring layer, 116R: coloring layer, 121: protective layer, 122: insulating layer, 123: insulating layer, 124a: pixel, 124b: pixel, 125: insulating layer, 126: resin layer, 128: layer, 140: connection portion, 150: pixel, 170: substrate, 171: adhesive layer

1. An electronic device comprising:
a first display device;
a second display device;
an eyepiece lens; and
a first lens,
wherein the first display device is configured to display a first image,
wherein the second display device is configured to display a second image,
wherein a pixel density of the first display device is equal to a pixel density of the second display device,
wherein the first image is presented through the eyepiece lens, and
wherein the second image is magnified by the first lens and presented through the eyepiece lens.

2. An electronic device comprising:
a first display device;
a second display device;
a first half mirror;
an eyepiece lens; and
a first lens,
wherein the first display device is configured to display a first image,
wherein the second display device is configured to display a second image,
wherein the first display device is at a position so that the first image is reflected by the first half mirror and enters the eyepiece lens,
wherein the second display device is at a position so that the second image passes through the first half mirror and enters the eyepiece lens,
wherein the first lens is between the second display device and the first half mirror,
wherein a pixel density of the first display device is equal to a pixel density of the second display device,
wherein the first image is presented with a first viewing angle through the eyepiece lens, and
wherein the second image is presented with a second viewing angle greater than the first viewing angle through the eyepiece lens.

3. An electronic device comprising:
a first display device;
a second display device;
a first half mirror;
an eyepiece lens; and
a first lens,
wherein the first display device is configured to display a first image,
wherein the second display device is configured to display a second image,
wherein the first display device is at a position so that the first image passes through the first half mirror and enters the eyepiece lens,
wherein the second display device is at a position so that the second image is reflected by the first half mirror and enters the eyepiece lens,
wherein the first lens is between the second display device and the first half mirror,
wherein a pixel density of the first display device is equal to a pixel density of the second display device,
wherein the first image is presented with a first viewing angle through the eyepiece lens, and
wherein the second image is presented with a second viewing angle greater than the first viewing angle through the eyepiece lens.

4. The electronic device according to claim 2, further comprising a second lens,
wherein the second lens is provided between the first display device and the first half mirror.

5. The electronic device according to claim 2,
wherein the first viewing angle is greater than or equal to 5° and less than or equal to 30°, and
wherein the second viewing angle is greater than the first viewing angle and less than or equal to 220°.

6. The electronic device according to claim 2, wherein an outline of the first image is a circle or an ellipse.

7. The electronic device according to claim 2,
wherein a center portion of the first image is shown at a first resolution,
wherein a surrounding portion outside the center portion is shown at a second resolution that is lower than the first resolution, and
wherein the second resolution is higher than or equal to a resolution of the second image when the second image is seen through the eyepiece lens.

8. The electronic device according to claim 2,
wherein the pixel density of each of the first display device and the second display device is higher than or equal to 1000 ppi and lower than or equal to 20000 ppi.

9. The electronic device according to claim 2, further comprising:
a third display device;
a third lens; and
a second half mirror,
wherein the third display device is configured to display a third image,
wherein the third display device is at a position so that the third image is reflected by the second half mirror and enters the eyepiece lens, and
wherein the third lens is between the third display device and the second half mirror.

10. The electronic device according to claim 1,
wherein each of the first display device and the second display device comprises a plurality of light-emitting elements and a plurality of color filters, and
wherein each of the light-emitting elements comprises an organic layer emitting white light.

11. The electronic device according to claim 10, wherein the organic layer is divided between two of the light-emitting elements adjacent to each other.

12. The electronic device according to claim 1,
wherein each of the first display device and the second display device comprises a first light-emitting element and a second light-emitting element, and
wherein the first light-emitting element and the second light-emitting element comprise different light-emitting materials.
